(19) United States
(12) Patent Application Publication
(10) Pub. No.: US 2025/0143120 A1
(43) Pub. Date: May 1, 2025

(54) DISPLAY MODULE INCLUDING SIGNAL PADS AND SIGNAL LINES AND AN ELECTRONIC APPARATUS INCLUDING THE SAME

(71) Applicant: SAMSUNG DISPLAY CO., LTD., YONGIN-SI (KR)

(72) Inventors: SUNGKYUN PARK, Yongin-si (KR); YONG-HWAN PARK, Yongin-si (KR); GYUNG-MIN KO, Yongin-si (KR)

(21) Appl. No.: 18/884,925

(22) Filed: Sep. 13, 2024

(30) Foreign Application Priority Data
Oct. 31, 2023 (KR) 10-2023-0147943

(51) Int. Cl. H10K 59/131; H10K 59/40

(52) U.S. Cl. CPC H10K 59/131; H10K 59/40

(57) ABSTRACT

A display module includes a display panel having a display region in which pixels are disposed and a non-display region having a first pad region in which first signal pads, electrically connected to the pixels respectively through first signal lines, are disposed. An input sensor is disposed on the display panel and it includes a sensing insulation layer including an organic material, and a sensing conductive layer. Each of the first signal pads includes first conductive patterns stacked along a thickness direction of the display panel. At least one of the first conductive patterns includes a same material as that of the sensing conductive layer. A first opening overlapping the first pad region is defined in the sensing insulation layer. A first residue conductive pattern, including the same material as that of the sensing conductive layer, is disposed on a border of the first opening.

### CROSS-REFERENCE TO RELATED APPLICATIONS

This U.S. non-provisional patent application claims priority under 35 U.S.C. § 119 to Korean Patent Application No. 10-2023-0147943, filed on Oct. 31, 2023, the entire contents of which are hereby incorporated by reference.

### TECHNICAL FIELD

The present disclosure relates to a display module, and more particularly, to a display module including signal pads and signal lines, and an electronic apparatus including the signal pads and signal lines.

### DISCUSSION OF THE RELATED ART

Multimedia electronic apparatuses, such as televisions, mobile phones, tablet computers, navigation systems, and game consoles, may include a display module that displays an image. These display modules may also be capable of detecting an external input such as a touch. The display module may be electrically bonded to a data driver that provides electrical signals necessary for displaying images.

### SUMMARY

A display module includes a display panel having a display region in which pixels are disposed, and a non-display region having a first pad region in which first signal pads, electrically connected to the pixels respectively through first signal lines, are disposed. An input sensor is disposed on the display panel, and has a sensing insulation layer including an organic material, and a sensing conductive layer. Each of the first signal pads includes first conductive patterns stacked along a thickness direction of the display panel, and at least one of the first conductive patterns includes a same material as that of the sensing conductive layer. A first opening overlapping the first pad region is defined in the sensing insulation layer. A first residue conductive pattern, including the same material as that of the sensing conductive layer, is disposed on a border of the first opening.

The first residue conductive pattern may be spaced apart from the first signal pads by a predetermined distance.

A minimum distance between the first residue conductive pattern and the first signal pads may be about 20 μm or more.

The sensing insulation layer might not overlap the first signal pads.

The first signal lines may cross the first residue conductive pattern and the display module may further include an insulation layer disposed between the first signal lines and the first residue conductive pattern.

Each of the pixels may include a transistor and a light-emitting element connected to the transistor, and the insulation layer may contain a same material as that of at least one of insulation layers disposed between the transistor and the light-emitting element.

Each of the pixels may include a transistor and a light-emitting element connected to the transistor. The transistor may include a semiconductor pattern and a gate electrode disposed on the semiconductor pattern. The display panel may further include first and second connection electrodes which connect the transistor to the light-emitting element.

The first conductive patterns may include a (1-1)-th conductive pattern including a same material as that of the gate electrode, a (1-2)-th conductive pattern including a same material as that of the first connection electrode, a (1-3)-th conductive pattern including a same material as that of the second connection electrode, and a (1-4)-th conductive pattern including the same material as that of the sensing conductive layer. The (1-1)-th conductive pattern to the (1-4)-th conductive pattern may be electrically connected to each other.

Each of the first signal lines may include a same material as that of at least one of the gate electrode and the second connection electrode.

Each of the first signal lines may include a same material as that of the second connection electrode. An insulation layer may be disposed between the first signal lines and the first residue conductive pattern. The first residue conductive pattern may be spaced at least about 20 μm apart from an end of the insulation layer.

The non-display region may further include a second pad region in which second signal pads are disposed. The second signal pads may be spaced further apart from the display region than the first signal pads are. and the second signal pads may be electrically connected to the pixels respectively through second signal lines. Each of the second signal pads may include second conductive patterns stacked along a thickness direction of the display panel and at least one of the second conductive patterns may contain the same material as that of the sensing conductive layer. A second opening overlapping the second pad region may be defined in the sensing insulation layer. A second residue conductive pattern, including the same material as that of the sensing conductive layer, may be disposed on a border of the second opening.

The second residue conductive pattern may be spaced apart from the second signal pads by a predetermined distance.

The second signal lines may include a (2-1)-th signal line, and a (2-2)-th signal line which electrically connects between the (2-1)-th signal line and the second signal pads, the (2-2)-th signal line may cross the second residue conductive pattern, and the display module may further include an insulation layer disposed between the (2-2)-th signal line and the second residue conductive pattern.

Each of the pixels may include a transistor and a light-emitting element connected to the transistor. The transistor may include a semiconductor pattern and a gate electrode disposed on the semiconductor pattern. The display panel may further include first and second connection electrodes which connect the transistor to the light-emitting element. The (2-1)-th signal line may contain the same material as that of the sensing conductive layer, and the (2-2)-th signal line may contain a same material as that of the second connection electrode.

S minimum distance between the second signal pads may be about 10 μm or more.

The non-display region may further include a third pad region in which test pads are disposed. The test pads may be spaced further apart from the display region than the second signal pads are. The test pads may be electrically connected to the pixels respectively through third signal lines. Each of the test pads may include third conductive patterns stacked along a thickness direction of the display panel, and at least one of the third conductive patterns may contain the same material as that of the sensing conductive layer. A third opening overlapping the third pad region may be defined in the sensing insulation layer. A third residue conductive pattern, including the same material as that of the sensing conductive layer, may be disposed on a border of the third opening.

The test pads may be bonded to a test circuit board through a conductive adhesive layer.

An electronic apparatus includes a display panel having a display region in which pixels are disposed, and a non-display region having first and second pad regions in which first and second signal pads, electrically connected to the pixels respectively through signal lines, are disposed. An input sensor is disposed on the display panel, and includes a sensing insulation layer including an organic material, and a sensing conductive layer. A data driver is disposed on the non-display region, and is electrically connected to the first signal pads by a first conductive adhesive layer. A flexible circuit board is disposed on the non-display region, and is electrically connected to the second signal pads by a second conductive adhesive layer. Each of the first signal pads includes first conductive patterns stacked along a thickness direction of the display panel, and at least one of the first conductive patterns includes a same material as that of the sensing conductive layer. A first opening overlapping the first pad region is defined in the sensing insulation layer. A first residue conductive pattern, including the same material as that of the sensing conductive layer, is disposed on a border of the first opening.

The first residue conductive pattern may be spaced apart from the first signal pads by a predetermined distance.

In the non-display region, each of the second signal pads may include second conductive patterns stacked along a thickness direction of the display panel, and at least one of the second conductive patterns may contain the same material as that of the sensing conductive layer, a second opening overlapping the second pad region may be defined in the sensing insulation layer. A second residue conductive pattern, including the same material as that of the sensing conductive layer, may be disposed on a border of the second opening.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a perspective view of an electronic apparatus according to an embodiment of the inventive concept;

FIG. 2 is an exploded perspective view of an electronic apparatus according to an embodiment of the inventive concept;

FIG. 3 is a cross-sectional view of a display module according to an embodiment of the inventive concept;

FIG. 4 is a plan view of a display panel according to an embodiment of the inventive concept;

FIG. 5 is a plan view of an input sensor according to an embodiment of the inventive concept;

FIG. 6 is a perspective view of an electronic apparatus according to an embodiment of the inventive concept;

FIG. 7 is a cross-sectional view of a display module according to an embodiment of the inventive concept;

FIG. 8 is an enlarged plan view of a display module according to an embodiment of the inventive concept;

FIG. 9A is a cross-sectional view taken along line I-I′ of FIG. 8 according to an embodiment of the inventive concept;

FIG. 9B is a cross-sectional view taken along line II-II′ of FIG. 8 according to an embodiment of the inventive concept;

FIG. 10 is an enlarged plan view of a display module according to an embodiment of the inventive concept;

FIG. 11A is a cross-sectional view taken along line III-III′ of FIG. 10 according to an embodiment of the inventive concept;

FIG. 11B is a cross-sectional view taken along line IV-IV′ of FIG. 10 according to an embodiment of the inventive concept;

FIG. 12 is an enlarged plan view of a display module according to an embodiment of the inventive concept;

FIG. 13A is a cross-sectional view taken along line V-V′ of FIG. 12 according to an embodiment of the inventive concept;

FIG. 13B is a cross-sectional view taken along line VI-VI′ of FIG. 12 according to an embodiment of the inventive concept;

FIG. 14 is a perspective view of an electronic apparatus according to an embodiment of the inventive concept;

FIG. 15 is an enlarged plan view of a display module according to an embodiment of the inventive concept;

FIG. 16 is a cross-sectional view taken along line VII-VII′ of FIG. 15 according to an embodiment of the inventive concept;

FIG. 17A is a cross-sectional view of a test pad according to an embodiment of the inventive concept; and

FIG. 17B is a cross-sectional view of a test pad according to Comparative Example.

### DETAILED DESCRIPTION

In this specification, it will be understood that when an element (or a region, a layer, a portion, or the like) is referred to as being “on”, “connected to”, “coupled to” another element, it may be directly disposed on, connected or coupled to the other element, or intervening elements may be disposed therebetween.

Like reference numerals or symbols may refer to like elements throughout the drawings and the specification. While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not necessarily be limited by these terms. These terms are used to distinguish one element, component, region, layer or section from another element, component, region, layer or section. Thus, a first element, component, region, layer or section discussed below could be termed a second element, component, region, layer or section without departing from the scope of the inventive concept. Similarly, a second element, component, region, layer or section may be termed a first element, component, region, layer or section. As used herein, the singular forms, “a”, “an” and “the” are intended to include the plural forms as well, unless the context clearly indicates otherwise.

Also, terms of “below”, “on lower side”, “above”, “on upper side”, or the like may be used to describe the relationships of the elements illustrated in the drawings. These terms have relative concepts and are described on the basis of the directions indicated in the drawings.

It will be further understood that the terms “includes” and/or “have”, when used in this specification, specify the presence of stated features, integers, steps, operations, elements, components, and/or groups thereof, but do not preclude the presence or addition of one or more other features, integers, steps, operations, elements, components, and/or groups thereof.

Hereinafter, embodiments of the inventive concept are described with reference to the accompanying drawings.

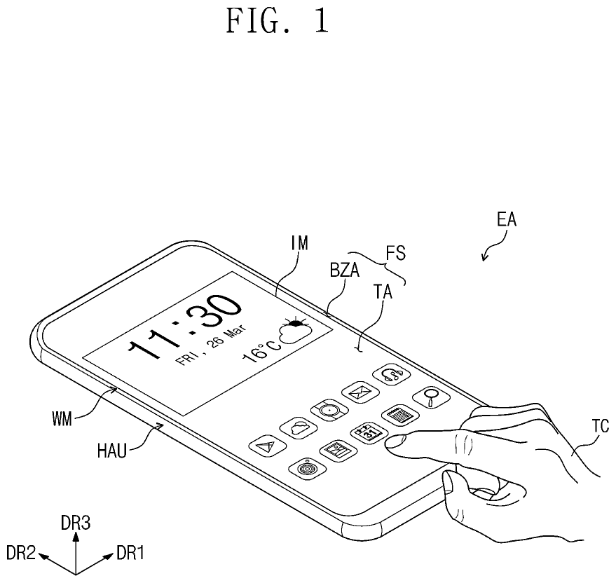

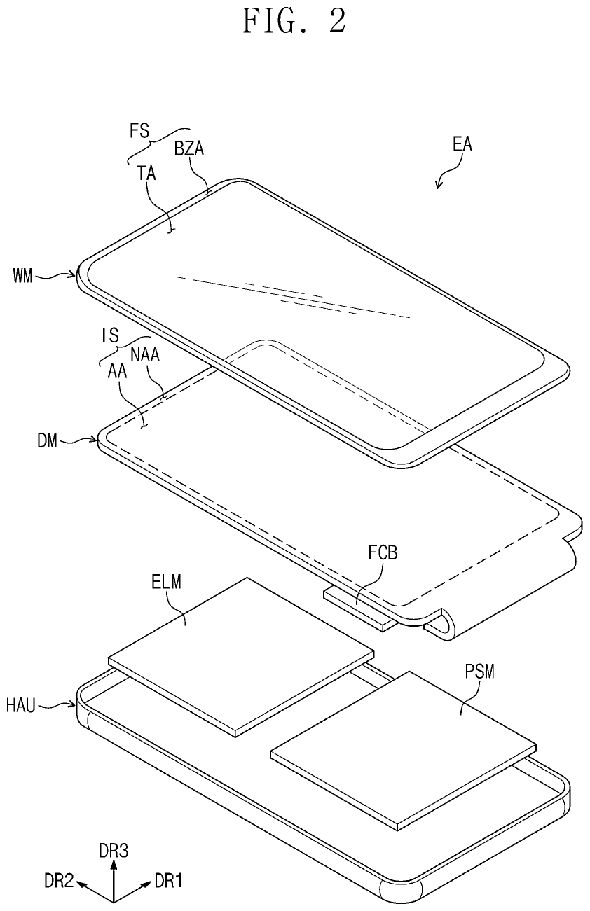

FIG. 1 is a perspective view of an electronic apparatus EA according to an embodiment of the inventive concept. FIG. 2 is an exploded perspective view of the electronic apparatus EA according to an embodiment of the inventive concept.

Referring to FIGS. 1 and 2, the electronic apparatus EA may be activated in response to electrical signals, display an image IM, and detect an external input TC. For example, the electronic apparatus EA may include apparatuses such as a computer monitor, a mobile phone, a tablet computer, a navigation system, and a game console. However, the above-mentioned embodiments of the electronic apparatus EA are examples, and the electronic apparatus is not necessarily limited to any one embodiment unless it departs from the concept of the inventive concept. In this embodiment, the electronic apparatus EA is exemplarily illustrated as the mobile phone.

The electronic apparatus EA may have a rectangular shape, in a plan view, having a pair of short sides extending in a first direction DR1 and a pair of long sides extending in a second direction DR2 crossing the first direction DR1. However, an embodiment of the inventive concept is not necessarily limited thereto, and the electronic apparatus EA may have various shapes such as a circular and polygonal shapes.

In this embodiment, a third direction DR3 may be defined as a direction perpendicular to a plane defined by the first direction DR1 and the second direction DR2. A front surface (or upper surface) and a rear surface (or lower surface) of each of the many elements constituting the electronic apparatus EA may be opposed to each other in the third direction DR3, and the normal direction of each of the front surface and the rear surface may be substantially parallel to the third direction DR3. The distance between the front surface and the rear surface defined along the third direction DR3 may correspond to the thickness of the given element.

In this specification, “in a plan view” may be defined as a state when viewed from the third direction DR3. In this specification, “in a cross-sectional view” may be defined as a state when viewed from the first direction DR1 or the second direction DR2. Directions indicated by the first to third directions DR1, DR2, and, DR3 may be relative concepts, and may thus be changed to other directions.

The electronic apparatus EA may be rigid or flexible. “To be flexible” may mean having bendable characteristics, and may include from a completely folding structure to a structure bendable at the level of a few nanometers. For example, a flexible electronic apparatus EA may include a curved electronic apparatus, a rollable electronic apparatus, or a foldable electronic apparatus.

The electronic apparatus EA may display the image IM through a display surface FS that is parallel to each of the first direction DR1 and the second direction DR2. The image IM may include a still image as well as a dynamic (e.g., moving) image. FIG. 1 illustrates a clock and icons as an example of the image IM.

The display surface FS of the electronic apparatus EA may include only a flat surface, or may also further include a curved surface bent from at least one side of the flat surface. The display surface FS may correspond to a front surface of the electronic apparatus EA, and at the same time, correspond to a front surface of a window WM. Hereinafter, the display surface FS of the electronic apparatus EA and the front surface FS of the window WM are denoted as the same reference symbol.

The electronic apparatus EA, according to an embodiment, may detect the external input TC. The external input TC may include various types of inputs such as power, pressure, temperature, or light. In this embodiment, the external input TC is illustrated as a user's hand applied to the front surface of the electronic apparatus EA. However, this is exemplarily illustrated, and the external input TC may include an input by a pen/stylus or an input applied in proximity to the electronic apparatus EA such as hovering.

The electronic apparatus EA may detect a user's input through the display surface FS defined on the front surface, and respond to the detected input signal. However, the region of the electronic apparatus EA detecting the external input TC is not necessarily limited to the front surface of the electronic apparatus EA, and may vary according to the design of the electronic apparatus EA. For example, the electronic apparatus EA may also detect the user's input applied to a side surface or rear surface of the electronic apparatus EA.

The electronic apparatus EA may include a window WM, a display module DM, an electronic module ELM, a power module PSM, and a housing HAU. The window WM may be coupled to the housing HAU to form the exterior of the electronic apparatus EA.

The window WM may be disposed on the display module DM. The window WM may cover a front surface IS of the display module DM, and may protect the display module DM from external impact and scratches. The window WM may be bonded to the display module DM through an adhesive layer.

The window WM may include an optically transparent insulating material. For example, the window WM may include glass or synthetic resin as a base film. The window WM may have a single-layer or multi-layer structure. For example, the multi-layer window WM may include synthetic resin films bonded by an adhesive, or include a glass film and a synthetic resin film bonded by an adhesive. The window WM may further include a functional layer, disposed on the transparent base film, such as an anti-fingerprint layer, a phase control layer, and/or a hard-coating layer.

The front surface FS of the window WM may correspond to the front surface of the electronic apparatus EA. The front surface FS of the window WM may include a transmission region TA and a bezel region BZA.

The transmission region TA may be an optically transparent region. The transmission region TA may transmit the image IM provided by the display module DM. In this embodiment, the transmission region TA is illustrated in a quadrilateral shape, but the shape is not necessarily limited thereto, and the transmission region TA may have various shapes.

The bezel region BZA may be a region having a lower light transmittance than that of the transmission region TA. The bezel region BZA may correspond to a region printed with a material having a predetermined color. The bezel region BZA may prevent light transmission, and thus prevent a component of the display module DM, disposed overlapping the bezel region BZA, from being viewed from the outside.

The bezel region BZA may be adjacent to the transmission region TA. The shape of the transmission region TA may be substantially defined by the bezel region BZA. For example, the bezel region BZA may be disposed outside the transmission region TA, and may thus surround the transmission region TA. However, this is exemplarily illustrated, and the bezel region BZA might be adjacent only to one side of the transmission region TA, or disposed on a side surface, not the front surface, of the electronic apparatus EA. In addition, the bezel region BZA may also be omitted.

The display module DM may be disposed between the window WM and the housing HAU. The display module DM may display the image IM and detect the external input TC. The image IM may be displayed on the front surface IS of the display module DM. The front surface IS of the display module DM may include an active region AA and a peripheral region NAA.

The active region AA may be activated in response to electrical signals. For example, the active region AA may be a region in which the image IM is displayed, and at the same time, a region in which the external input TC is detected. The active region AA may overlap at least a portion of the transmission region TA. Accordingly, a user may view the image IM or provide the external input TC through the transmission region TA. However, this is an example, in the active region AA, a region in which the image IM is displayed and a region in which the external input TC is detected may also be separated, and the active region AA is not necessarily limited to any one embodiment of the inventive concept.

The peripheral region NAA may be adjacent to the active region AA. For example, the peripheral region NAA may at least partially surround the active region AA, which may mean that the peripheral region NAA is proximate to the active region AA on one or more sides thereof and may be proximate to the active region AA on opposing sides or may fully surround the active region AA. The phrase “at least partially surrounding” may be similarly interpreted where used elsewhere within the instant specification. In the peripheral region NAA, a driving circuit, driving wires, or the like may be disposed for driving the active region AA. The peripheral region NAA may overlap at least a portion of the bezel region BZA, and the bezel region BZA may prevent components disposed in the peripheral region NAA from being viewed from the outside.

The display module DM may include a display panel and an input sensor. The display panel may display the image IM, and the input sensor may detect the external input TC. This will be described in detail later.

A portion of the display module DM may be bent with respect to a bending axis extending in the first direction DR1. For example, the portion of the display module DM may be bent toward a rear surface of the display module DM corresponding to the active region AA. The bent portion of the display module DM may be connected to a flexible circuit board FCB, and accordingly, the flexible circuit board FCB may overlap the display module DM in a plan view.

The flexible circuit board FCB may be electrically connected to the display module DM through one side of the display module DM. The flexible circuit board FCB may generate an electrical signal to be provided to the display module DM, or receive a signal generated from the display module DM to calculate the result value including information on a position where the external input TC is detected or on the intensity of the detected external input TC.

The electronic module ELM and the power module PSM may be disposed under the display module DM. The electronic module ELM and the power module PSM may be electrically connected through a separate circuit board.

The power module PSM may supply power necessary for an operation of the electronic apparatus EA. For example, the power module PSM may include a general battery module.

The electronic module ELM may include various functional modules that operate the electronic apparatus EA. For example, the electronic module ELM may include a control module, a wireless communication module, an image input module, a sound input module, a sound output module, a memory, an optical module, an external interface module, and the like. The electronic module ELM may include a main circuit board, and the modules of the electronic module ELM may be mounted on the main circuit board, or electrically connected to the main circuit board through a separate circuit board.

The control module of the electronic module ELM may control the entire operation of the electronic apparatus EA. For example, the control module may activate or deactivate the display module DM in response to a user's input. The control module may include at least one microprocessor. The optical module of the electronic module ELM may include a camera module, a proximity sensor, a biometric sensor that detects a part of a user's body (for example, a fingerprint, iris, or face), a light-outputting lamp, or the like.

The housing HAU may be coupled to the window WM to provide an inner space that accommodates the display module DM, the electronic module ELM, the power module PSM, and the flexible circuit board FCB. The housing HAU may include a material having relatively high rigidity. For example, the housing HAU may include a plurality of frames and/or plates including glass, plastic, or metal, or composed of a combination thereof. The housing HAU may absorb impact applied from the outside, or prevent foreign substances/moisture, etc. from penetrating therein, and may thus protect the components of the electronic apparatus EA accommodated in the housing HAU.

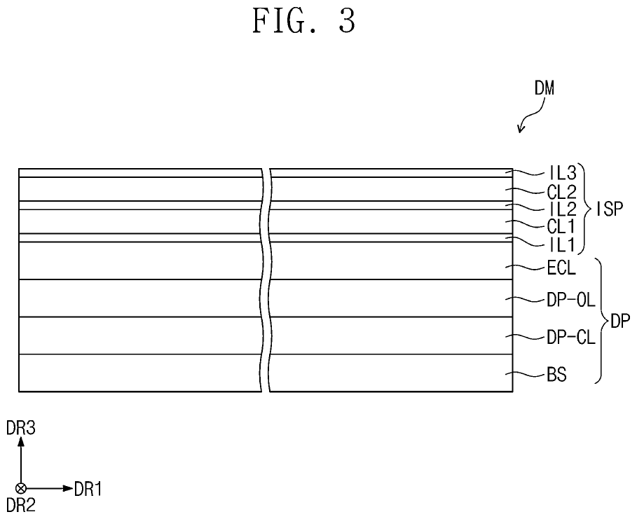

FIG. 3 is a cross-sectional view of a display module DM according to an embodiment of the inventive concept.

Referring to FIG. 3, the display module DM may include a display panel DP and an input sensor ISP. The input sensor ISP may be disposed on the display panel DP. For example, the input sensor ISP may be directly disposed on the display panel DP. In this embodiment, “the input sensor ISP being directly disposed on the display panel DP” means that the input sensor ISP is formed on the display panel DP through a continuous process, and thus coupled to the display panel DP without the use of a separate adhesive layer. For example, components of the input sensor ISP may be formed on a base surface provided from the display panel DP.

The display panel DP may display an image in response to electrical signals. The display panel DP, according to an embodiment, may be an emission-type display panel, but is not necessarily particularly limited thereto. For example, the display panel DP may be an organic light-emitting diode (OLED) display panel, an inorganic light-emitting display panel, or a quantum-dot light-emitting display panel. A light-emitting layer of the organic light-emitting diode display panel may include an organic light-emitting material, and a light-emitting layer of the inorganic light-emitting display panel may include an inorganic light-emitting material. A light-emitting layer of the quantum-dot light-emitting display panel may include quantum dots, quantum rods, and the like. Hereinafter, the display panel DP is described as the organic light-emitting diode display panel.

The display panel DP may include a base substrate BS, a circuit layer DP-CL, a display element layer DP-OL, and an encapsulation layer ECL sequentially stacked along a third direction DR3.

The base substrate BS may be a rigid substrate, or a flexible substrate capable of bending, folding, rolling, or the like, to a noticeable extent without cracking or otherwise sustaining damage. For example, the base substrate BS may be a glass substrate, a metal substrate, a polymer substrate, or the like. The base substrate BS may provide a base surface on which the circuit layer DP-CL is disposed.

The base substrate BS may include an inorganic layer, an organic layer, or a composite material layer. The base substrate BS may have a single-layer or multi-layer structure. For example, the multi-layer base substrate BS may include synthetic resin layers and a multi-layer or single-layer inorganic layer disposed between the synthetic resin layers. The synthetic resin layer may include an acrylate-based resin, a methacrylate-based resin, polyisoprene, a vinyl-based resin, an epoxy-based resin, a urethane-based resin, a cellulose-based resin, a siloxane-based resin, a polyamide-based resin, a perylene-based resin, or the like, but the material of the synthetic resin layer is not necessarily limited thereto.

The circuit layer DP-CL may be disposed on the base substrate BS. The circuit layer DP-CL may include at least one insulation layer, a semiconductor pattern, and a conductive pattern. The insulation layer, the semiconductor pattern, and the conductive pattern included in the circuit layer DP-CL may form driving elements such as a transistor, signal lines, and pads.

The display element layer DP-OL may be disposed on the circuit layer DP-CL. The display element layer DP-OL may include light-emitting elements each of which emits light. For example, the light-emitting elements may include an organic light-emitting element, an inorganic light-emitting element, a micro-LED, a nano-LED, or the like. The light-emitting elements of the display element layer DP-OL may be electrically connected to the driving elements of the circuit layer DP-CL to emit light in response to electrical signals provided by the driving elements.

The encapsulation layer ECL may be disposed on the display element layer DP-OL to seal the light-emitting elements. The encapsulation layer ECL may increase optical efficiency of the display element layer DP-OL, or include at least one thin film for protecting the display element layer DP-OL. For example, the encapsulation layer ECL may include an inorganic film and/or an organic film. The inorganic film of the encapsulation layer ECL may protect the light-emitting elements from moisture/oxygen. The organic film of the encapsulation layer ECL may protect the light-emitting elements from foreign substances such as dust particles.

The input sensor ISP may detect an external input and provide an input signal including information on the external input, so that the display panel DP may display an image corresponding to the external input. The input sensor ISP may operate in various types such as a capacitance, resistive, infrared, sound wave, or pressure type, and the operating type of the input sensor ISP is not necessarily limited to any one as long as being capable of detecting the external input. In this embodiment, the input sensor ISP is described as an input-sensing panel that operates in the capacitance type.

The input sensor ISP may include a base layer IL1, a first sensing conductive layer CL1, a first sensing insulation layer IL2, a second sensing conductive layer CL2, and a second sensing insulation layer IL3 sequentially stacked along the third direction DR3. The base layer IL1 of the input sensor ISP may be in contact with the encapsulation layer ECL. However, an embodiment of the inventive concept is not necessarily limited thereto, and at least one of the base layer IL1 or the second sensing insulation layer IL3 may be omitted.

The first sensing conductive layer CL1 and the second sensing conductive layer CL2 may each have a single-layer or multi-layer structure. A conductive layer with the multi-layer structure may include at least two layers that are transparent conductive layers and/or metal layers. The conductive layer with the multi-layer structure may include the metal layers including different metal. The transparent conductive layer may include indium tin oxide (ITO), indium zinc oxide (IZO), zinc oxide (ZnO), indium tin zinc oxide (ITZO), PEDOT, metal nanowires, and/or graphene. The metal layer may include molybdenum, silver, titanium, copper, aluminum, and/or an alloy thereof. For example, the first sensing conductive layer CL1 and the second sensing conductive layer CL2 may each have a two-layer structure, for example, of ITO/copper, or an embodiment of the inventive concept is not necessarily limited thereto. The first sensing conductive layer CL1 and the second sensing conductive layer CL2 may each have a three-layer structure of titanium/aluminum/titanium.

The first sensing conductive layer CL1 and the second sensing conductive layer CL2 may include sensing conductive patterns. The sensing conductive patterns of the first sensing conductive layer CL1 and the second sensing conductive layer CL2 may form sensing electrodes constituting the input sensor ISP and sensing lines connected thereto.

The base layer IL1, the first sensing insulation layer IL2, and the second sensing insulation layer IL3 may each include an inorganic film and/or organic film. For example, the inorganic film may include aluminum oxide, titanium oxide, silicon oxide, silicon oxynitride, zirconium oxide, and/or hafnium oxide, and the organic film may include an acrylate-based resin, a methacrylate-based resin, polyisoprene, a vinyl-based resin, an epoxy-based resin, a urethane-based resin, a cellulose-based resin, a siloxane-based resin, a polyimide-based resin, a polyamide-based resin, and/or a perylene-based resin. However, the materials of the inorganic film and the organic film are not necessarily limited to the above examples. In an embodiment, the base layer IL1 may include the inorganic film, and the first sensing insulation layer IL2 and the second sensing insulation layer IL3 may each include the organic film including an organic material.

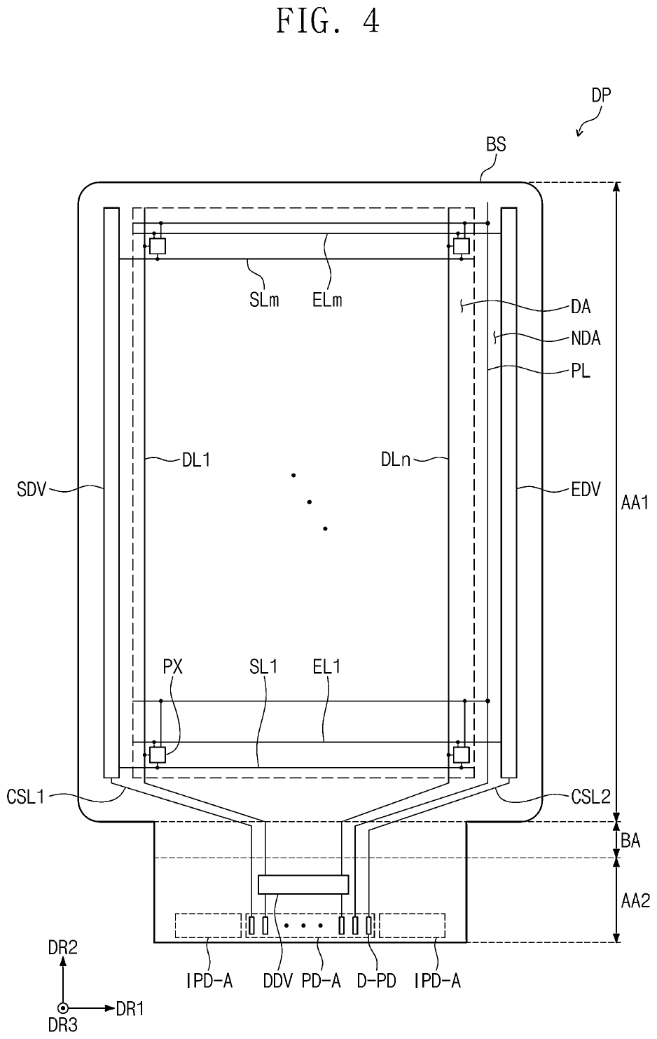

FIG. 4 is a plan view of a display panel DP according to an embodiment of the inventive concept.

Referring to FIG. 4, the display panel DP may include a base substrate BS, pixels PX, signal lines SL1 to SLm, DL1 to DLn, EL1 to ELm, CSL1, CSL2, and PL electrically connected to the pixels PX, a scan driver SDV, an emission driver EDV, a data driver DDV, and display pads D-PD.

The base substrate BS may provide a base surface on which electrical elements, lines, etc., of the display panel DP are disposed. The base substrate BS may include a first base region AA1, a bending region BA, and a second base region AA2 separated in a second direction DR2. The bending region BA may extend from the first base region AA1 in the second direction DR2. The second base region AA2 may extend from the bending region BA in the second direction DR2. Therefore, the first base region AA1 and the second base region AA2 may be spaced apart from each other with the bending region BA interposed therebetween.

The first base region AA1 may include a display region DA. The display region DA may be a region where light-emitting elements of the pixels PX are disposed. Accordingly, the pixels PX may display an image through the display region DA. The display region DA may correspond to the active region AA (see FIG. 2) of the display module DM (see FIG. 2), and overlap the transmission region TA (see FIG. 2).

The first base region AA1 except the display region DA, the bending region BA, and the second base region AA2 may be defined as a non-display region NDA. The non-display region NDA may be a region which is adjacent to the display region DA and in which an image is not displayed. The non-display region NDA may at least partially surround the display region DA.

In the non-display region NDA, the scan driver SDV, the emission driver EDV, and the data driver DDV for driving the pixels PX and the display pads D-PD electrically connected to the signal lines SL1 to SLm, DL1 to DLn, EL1 to ELm, CSL1, CSL2, and PL may be disposed. The signal lines SL1 to SLm, DL1 to DLn, EL1 to ELm, CSL1, CSL2, and PL, electrically connected to the pixels PX, may extend to be disposed on the non-display region NDA.

The bending region BA may be a region bendable with respect to a bending axis extending in a first direction DR1. For example, the bending region BA may be bent toward a rear surface of the display panel DP corresponding to the first base region AA1. The second base region AA2, extending from one side of the bending region BA, may overlap the first base region AA1 in a plan view according to a bending operation of the bending region BA. For example, the second base region AA2 may be disposed on the rear surface of the display panel DP corresponding to the first base region AA1.

The width of each of the bending region BA and the second base region AA2 may be smaller than the width of the first base region AA1 in the first direction DR1. Since the bending region BA has a smaller width than that of the first base region AA1 in a direction parallel to the bending axis, the bending region BA may be easily bendable. However, this is exemplarily illustrated, and at least one of the width of the bending region BA or the width of the second base region AA2 may be the same as the width of the first base region AA1 in the first direction DR1, and the width is not necessarily limited to any one embodiment of the inventive concept.

The second base region AA2 may be a region, due to the bending of the bending region BA, positioned under the first base region AA1 and provided flat. The second base region AA2 may be a region where the data driver DDV and the signal lines extending toward the display pads D-PD via the bending region BA, among the signal lines SL1 to SLm, DL1 to DLn, EL1 to ELm, CSL1, CSL2, and PL, are disposed.

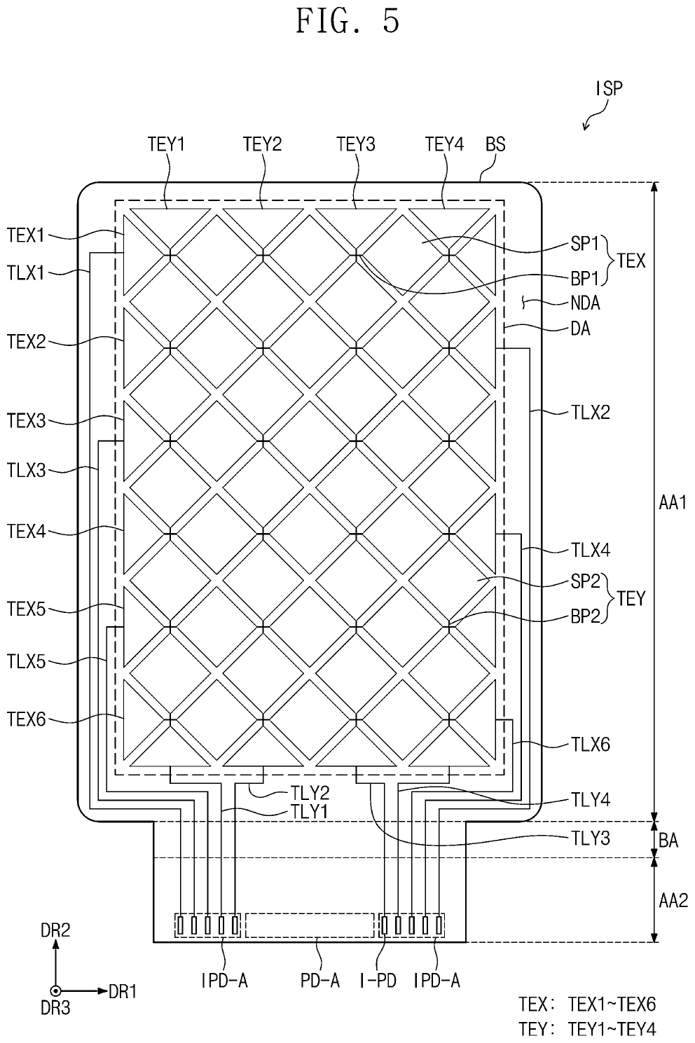

A region where the display pads D-PD are disposed and a region where sensing pads I-PD (see FIG. 5), to be described later, are disposed may be distinguished as a display pad region PD-A and a sensing pad region IPD-A, respectively. FIG. 4 exemplarily illustrates that the display pad region PD-A and the sensing pad region IPD-A are separated in the first direction DR1. For example, the sensing pad region IPD-A may be provided adjacent to both sides of the second base region AA2 in the first direction DR1, and the display pad region PD-A may be provided to the center portion. However, an embodiment of the inventive concept is not necessarily limited thereto, and the arrangement positions of the display pads D-PD and the sending pads I-PD (see FIG. 5) may be variously changed.

The flexible circuit board FCB (see FIG. 2) may be disposed on the second base region AA2 where the display pads D-PD and the sensing pads I-PD (see FIG. 5) are disposed, and thus electrically connected to the display pads D-PD and the sensing pads I-PD (see FIG. 5). The flexible circuit board FCB (see FIG. 2), disposed adjacent to a lower end of the second base region AA2, may be positioned on the rear surface of the display panel DP according to the bending operation of the bending region BA. Since the second base region AA2 and the flexible circuit board FCB (see FIG. 2) are positioned below the first base region AA1 on a front surface of the electronic apparatus EA (see FIG. 2), the bezel area of the electronic apparatus EA (see FIG. 2) may be reduced.

The pixels PX may each include a pixel driving circuit composed of transistors (for example, a switching transistor, a driving transistor, etc.) and at least one capacitor, and a light-emitting element electrically connected to the pixel driving circuit. The pixels PX may generate light in response to an electrical signal applied to each of the pixels PX, and display an image through the display region DA. According to an embodiment, some of the pixels PX may include a transistor disposed in the non-display region NDA, and the pixel PX is not necessarily limited to any one embodiment of the inventive concept.

The scan driver SDV and the emission driver EDV may be disposed in the non-display region NDA corresponding to the first base region AA1. The data driver DDV may be disposed in the non-display region NDA corresponding to the second base region AA2. In an embodiment, the data driver DDV may be provided as an integrated circuit chip mounted in the non-display region NDA of the display panel DP. However, an embodiment of the inventive concept is not necessarily limited thereto, and the data driver DDV may also be mounted on the flexible circuit board FCB (see FIG. 2).

The signal lines SL1 to SLm, DL1 to DLn, EL1 to ELm, CSL1, CSL2, and PL may include scan lines SL1 to SLm, data lines DL1 to DLn, emission lines EL1 to ELm, first and second control lines CSL1 and CSL2, and a power line PL. Here, m and n are positive integers.

The data lines DL1 to DLn may cross the scan lines SL1 to SLm and the emission lines EL1 to ELm while being insulated therefrom. For example, the scan lines SL1 to SLm may extend in the first direction DR1 to be electrically connected to the scan driver SDV. The data lines DL1 to DLn may extend in the second direction DR2 to be electrically connected to the data driver DDV. The emission lines EL1 to ELm may extend in the first direction DR1 to be electrically connected to the emission driver EDV.

The power line PL may include a portion extending in the first direction DR1 and a portion extending in the second direction DR2. The portion extending in the first direction DR1 and the portion extending in the second direction DR2, of the power line PL, may be disposed on different layers, or disposed integrally on the same layer. The portion of the power line PL extending in the first direction DR1 may be electrically connected to the pixels PX and the portion extending in the second direction DR2. The portion of the power line PL extending in the second direction DR2 may be disposed in the non-display region NDA, and thus electrically connected to the display pads D-PD via the bending region BA and the second base region AA2 from the first base region AA1. The power line PL may provide a first voltage to the pixels PX.

The first control line CSL1 may be electrically connected to the scan driver SDV, and extend toward the lower end of the second base region AA2 via the bending region BA. The second control line CSL2 may be electrically connected to the emission driver EDV, and extend toward the lower end of the second base region AA2 via the bending region BA.

The display pads D-PD may be disposed adjacent to the lower end of the second base region AA2. On the second base region AA2, the display pads D-PD may be disposed closer to a lower end of the base substrate BS than the data driver DDV. The display pads D-PD may be spaced apart from each other in the first direction DR1. The power line PL, the first control line CSL1, and the second control line CSL2 may each be electrically connected to a corresponding display pad D-PD among the display pads D-PD. The data lines DL1 to DLn may each be electrically connected to a corresponding display pad D-PD, among the display pads D-PD, through the data driver DDV.

The display pads D-PD may be electrically connected to the flexible circuit board FCB (see FIG. 2) through an anisotropy conductive adhesive layer, and electrical signals provided from the flexible circuit board FCB (see FIG. 2) may be transmitted to the display panel DP through the display pads D-PD. However, the way of connecting the display pads D-PD and the flexible circuit board FCB (see FIG. 2) is not necessarily limited thereto.

The scan driver SDV may generate scan signals in response to a scan control signal. The scan signals may be applied to the pixels PX through the scan lines SL1 to SLm. The data driver DDV may generate data voltages corresponding to image signals in response to a data control signal. The data voltages may be applied to the pixels PX through the data lines DL1 to DLn. The emission driver EDV may generate emission signals in response to an emission control signal. The emission signals may be applied to the pixels PX through the emission lines EL1 to ELm.

The pixels PX may receive the data voltages in response to the scan signals. In response to the emission signals, the pixels PX may emit light of brightness corresponding to the data voltages, thereby generating an image. The emission time of the pixels PX may be controlled by the emission signals.

FIG. 5 is a plan view of an input sensor ISP according to an embodiment of the inventive concept. For the convenience of description, FIG. 5 schematically illustrates components of the input sensor ISP disposed on the previously-described base substrate BS.

In an embodiment, the input sensor ISP may operate in a mutual-cap type. Referring to FIG. 5, the input sensor ISP may include first sensing electrodes TEX: TEX1 to TEX6, second sensing electrodes TEY: TEY1 to TEY4, first sensing lines TLX1 to TLX6, second sensing lines TLY1 to TLY4, and sensing pads I-PD. However, an embodiment of the inventive concept is not necessarily limited thereto, and the input sensor ISP may operate in a self-cap type.

The first sensing electrodes TEX may each extend along a first direction DR1, and the first sensing electrodes TEX may be arranged along a second direction DR2. FIG. 5 exemplarily illustrates six first sensing electrodes TEX1 to TEX6. However, the number of the first sensing electrodes TEX included in the input sensor ISP is not necessarily limited thereto. One first sensing electrode TEX may include first sensing patterns SP1 arranged along the first direction DR1 and first connection patterns BP1 connecting the first sensing patterns SP1.

The second sensing electrodes TEY may each extend along the second direction DR2, and the second sensing electrodes TEY may be arranged along the first direction DR1. FIG. exemplarily illustrates four second sensing electrodes TEY1 to TEY4. However, the number of the second sensing electrodes TEY included in the input sensor ISP is not necessarily limited thereto. One second sensing electrode TEY may include second sensing patterns SP2 arranged along the second direction DR2 and second connection patterns BP2 connecting the second sensing patterns SP2.

The first sensing electrodes TEX and the second sensing electrodes TEY may be electrically insulated from each other. The input sensor ISP may detect an external input through change in capacitance between the first sensing electrodes TEX and the second sensing electrodes TEY. The first sensing electrodes TEX and the second sensing electrodes TEY may be disposed in a region corresponding to a display region DA of the base substrate BS. Accordingly, the electronic apparatus EA (see FIG. 1) may display an image through the display region DA, and at the same time, may detect an external input applied to the display region DA.

The first sensing lines TLX1 to TLX6 may be disposed on a non-display region NDA to be electrically connected to the first sensing electrodes TEX1 to TEX6, respectively. Some of the first sensing lines TLX1 to TLX6 may be disposed on the left side of the non-display region NDA, and the others may be disposed on the right side of the non-display region NDA. For example, the first sensing lines TLX1, TLX3, and TLX5, connected to the first sensing electrodes TEX1, TEX3, and TEX5 disposed on odd rows, may be respectively connected to the left sides of the first sensing electrodes TEX1, TEX3, and TEX5, and the first sensing lines TLX2, TLX4, and TLX6, connected to the first sensing electrodes TEX2, TEX4, and TEX6 disposed on even rows, may be respectively connected to the right sides of the first sensing electrodes TEX2, TEX4, and TEX6. However, the arrangement of the first sensing lines TLX1 to TLX6 is not necessarily limited thereto, and each of the first sensing lines TLX1 to TLX6 may be disposed on the left side of the non-display region NDA, or all of the first sensing lines TLX1 to TLX6 may be disposed on the right side of the non-display region NDA.

The first sensing lines TLX1 to TLX6 may each extend from a first base region AA1 toward a second base region AA2 via a bending region BA. The first sensing lines TLX1 to TLX6 may be electrically connected to the sensing pads I-PD disposed on the second base region AA2, respectively.

The second sensing lines TLY1 to TLY4 may be disposed on the non-display region NDA to be electrically connected to the second sensing electrodes TEY1 to TEY4, respectively. Some of the second sensing lines TLY1 to TLY4 may be disposed adjacent to the left side of the non-display region NDA, and the others may be disposed adjacent to the right side of the non-display region NDA. For example, the second sensing lines TLY1 and TLY2 electrically connected to the second sensing electrodes TEY1 and TEY2 disposed on the left side in the first direction DR1, among the second sensing electrodes TEY1 to TEY4, may be disposed adjacent to the left side of the first base region AA1, and the second sensing lines TLY3 and TLY4 electrically connected to the second sensing electrodes TEY3 and TEY4 disposed on the right side may be disposed adjacent to the right side of the first base region AA1. However, the arrangement of the second sensing lines TLY1 to TLY4 is not necessarily limited thereto.

The second sensing lines TLY1 to TLY4 may each extend from a region adjacent to a lower end of the first base region AA1 toward the second base region AA2 via the bending region BA. The second sensing lines TLY1 to TLY4 may be electrically connected to the sensing pads I-PD disposed on the second base region AA2, respectively.

Some of the sensing pads I-PD may be disposed in a region adjacent to the left side of the second base region AA2 in the first direction DR1, and the others may be disposed in a region adjacent to the right side of the second base region AA2. For example, the sensing pads I-PD may be divided into two groups spaced apart from each other with a display pad region PD-A interposed therebetween. However, the arrangement of the sensing pads I-PD is not necessarily limited thereto.

The sensing pads I-PD may be disposed on the same layer as the layer on which the display pads D-PD (see FIG. 4) are disposed. The sensing pads I-PD may be disposed on a different layer from the layer on which the first and second sensing lines TLX1 to TLX6 and TLY1 to TLY4 are disposed, and connected thereto through a contact hole. However, an embodiment of the inventive concept is not necessarily limited thereto, and the sensing pads I-PD may be disposed on a different layer from the layer on which the display pads D-PD (see FIG. 4) are disposed. For example, the sensing pads I-PD may be formed integrally on the same layer as the layer on which the first and second sensing lines TLX1 to TLX6 and TLY1 to TLY4 are disposed.

The first and second sensing lines TLX1 to TLX6 and TLY1 to TLY4 may be disposed above the components of the display panel DP (see FIG. 4) on a region corresponding to the non-display region NDA of the base substrate BS. Accordingly, the first and second sensing lines TLX1 to TLX6 and TLY1 to TLY4 may overlap the components of the display panel DP (see FIG. 4) on the bending region BA and the second base region AA2.

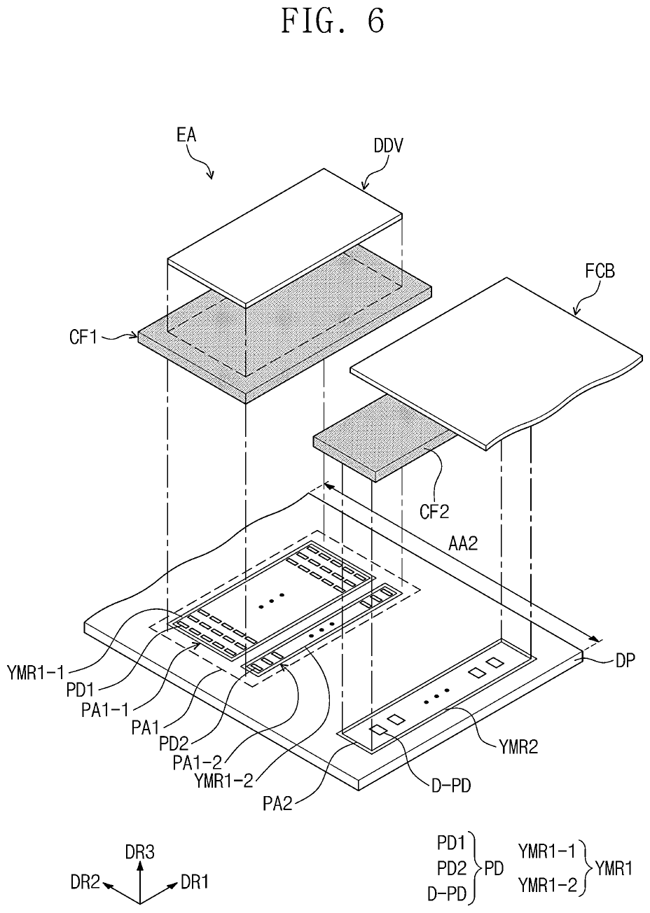

FIG. 6 is a perspective view of an electronic apparatus EA according to an embodiment of the inventive concept. FIG. 6 schematically illustrates some components of the electronic apparatus EA disposed in correspondence to a second base region AA2.

The second base region AA2 corresponds to a partial region of the non-display region NDA (see FIG. 4). As illustrated in FIG. 6, a region of the non-display region NDA (see FIG. 4), or the second base region AA2, to which a data driver DDV is bonded may be defined as a first pad region PA1, and a region to which a flexible circuit board FCB is bonded may be defined as a second pad region PA2. First signal pads PD1 and PD2 may be disposed in the first pad region PA1. Display pads D-PD may be disposed in the second pad region PA2.

The data driver DDV may be bonded to the first pad region PA1 through a first conductive adhesive layer CF1, and the flexible circuit board FCB may be bonded to the second pad region PA2 through a second conductive adhesive layer CF2. The first conductive adhesive layer CF1 and the second conductive adhesive layer CF2 may each be provided as an anisotropy conductive adhesive. For example, the first conductive adhesive layer CF1 and the second conductive adhesive layer CF2 may each include an adhesive resin and conductive particles dispersed in the adhesive resin.

However, an embodiment of the inventive concept is not necessarily limited thereto, and in an embodiment, the first conductive adhesive layer CF1 and/or the second conductive adhesive layer CF2 may be omitted. For example, the data driver DDV and the flexible circuit board FCB may be respectively bonded to the first pad region PA1 and the second pad region PA2 through ultrasonic bonding.

The display panel DP may include a plurality of pads PD. The plurality of pads PD may include the first signal pads PD1 and PD2 and the display pads D-PD (or second signal pads). The first signal pads PD1 and PD2 and the display pads D-PD (or second signal pads) may be pads each disposed on a transmission path of signals.

The first signal pads PD1 and PD2 may include (1-1)-th signal pads PD1 and (1-2)-th signal pads PD2. The (1-1)-th signal pads PD1 may be input pads which are disposed in correspondence to an output bump of the data driver DDV, and receive signals from the data driver DDV. The (1-2)-th signal pads PD2 may be output pads which are disposed in correspondence to an input bump of the data driver DDV, and output signals to the data driver DDV. The display pads D-PD may be panel input pads which receive signals from the flexible circuit board FCB.

The (1-1)-th signal pads PD1 may be electrically connected to the pixels PX (see FIG. 4) of the display panel DP through signal lines, respectively, and transmit/receive signals to/from the pixels PX (see FIG. 4). The (1-2)-th signal pads PD2 may each be electrically connected to a corresponding display pad D-PD, among the display pads D-PD, through a signal wire, and the display pads D-PD and the (1-2)-th signal pads PD2, which are electrically connected to each other, may transmit and receive signals therebetween.

The first pad region PA1 may include a first sub pad region PA1-1 and a second sub pad region PA1-2. The first sub pad region PA1-1 may be defined as a region where the (1-1)-th signal pads PD1 are disposed. The second sub pad region PA1-2 may be defined as a region where the (1-2)-th signal pads PD2 are disposed.

The (1-1)-th signal pads PD1 may be arranged along a first direction DR1 and a second direction DR2 in the first sub pad region PA1-1. (1-1)-th signal pads PD1 arranged along the first direction DR1, among the (1-1)-th signal pads PD1, may be defined as a pad row. FIG. 6 exemplarily illustrates that five pad rows are arranged along the second direction DR2. The arrangement of the (1-1)-th signal pads PD1 is not necessarily limited to any one embodiment of the inventive concept as long as at least two pad rows are arranged along the second direction DR2.

A first residue conductive pattern YMR1 may include a (1-1)-th residue conductive pattern YMR1-1 and a (1-2)-th residue conductive pattern YMR1-2. The first residue conductive pattern YMR1 may at least partially surround the first sub pad region PA1-1 and the second sub pad region PA1-2. The first residue conductive pattern YMR1 may be spaced apart from the (1-1)-th signal pads PD1 in a plan view. The first residue conductive pattern YMR1 may be spaced apart from the (1-2)-th signal pads PD2 in a plan view.

The (1-1)-th residue conductive pattern YMR1-1 may at least partially surround the first sub pad region PA1-1. The (1-1)-th residue conductive pattern YMR1-1 may include a first part extending along the first direction DR1 and a second part extending along the second direction DR2. The (1-1)-th residue conductive pattern YMR1-1 may have a quadrilateral shape defined as the first part and the second part. The (1-1)-th signal pads PD1 may be disposed inside the (1-1)-th residue conductive pattern YMR1-1. FIG. 6 illustrates the (1-1)-th residue conductive pattern YMR1-1 as a quadrilateral shape, but this is an example, and the shape of the (1-1)-th residue conductive pattern YMR1-1 may be changed as necessary. For example, the (1-1)-th residue conductive pattern YMR1-1 may have a closed curve or polygonal shape surrounding the first sub pad region PA1-1.

The (1-2)-th residue conductive pattern YMR1-2 may at least partially surround the second sub pad region PA1-2. The (1-2)-th residue conductive pattern YMR1-2 may include a first part extending along the first direction DR1 and a second part extending along the second direction DR2. The (1-2)-th residue conductive pattern YMR1-2 may have a quadrilateral shape defined as the first part and the second part. The (1-2)-th signal pads PD2 may be disposed inside the (1-2)-th residue conductive pattern YMR1-2. FIG. 6 illustrates the (1-2)-th residue conductive pattern YMR1-2 as a quadrilateral shape, but this is an example, and the shape of the (1-2)-th residue conductive pattern YMR1-2 may be changed as necessary. For example, the (1-2)-th residue conductive pattern YMR1-2 may have a closed curve or polygonal shape surrounding the second sub pad region PA1-2.

A second residue conductive pattern YMR2 may at least partially surround the second pad region PA2. The second residue conductive pattern YMR2 may include a first part extending along the first direction DR1 and a second part extending along the second direction DR2. The second residue conductive pattern YMR2 may have a quadrilateral shape defined as the first part and the second part. The display pads D-PD may be disposed inside the second residue conductive pattern YMR2. FIG. 6 illustrates the second residue conductive pattern YMR2 as a quadrilateral shape, but this is an example, and the shape of the second residue conductive pattern YMR2 may be changed as necessary. For example, the second residue conductive pattern YMR2 may have a closed curve or polygonal shape surrounding the second pad region PA2.

The (1-2)-th signal pads PD2 may be arranged along the first direction DR1 in the second sub pad region PA1-2. The (1-2)-th signal pads PD2 may be disposed as one pad row. However, the arrangement of the (1-2)-th signal pads PD2 is not necessarily limited thereto.

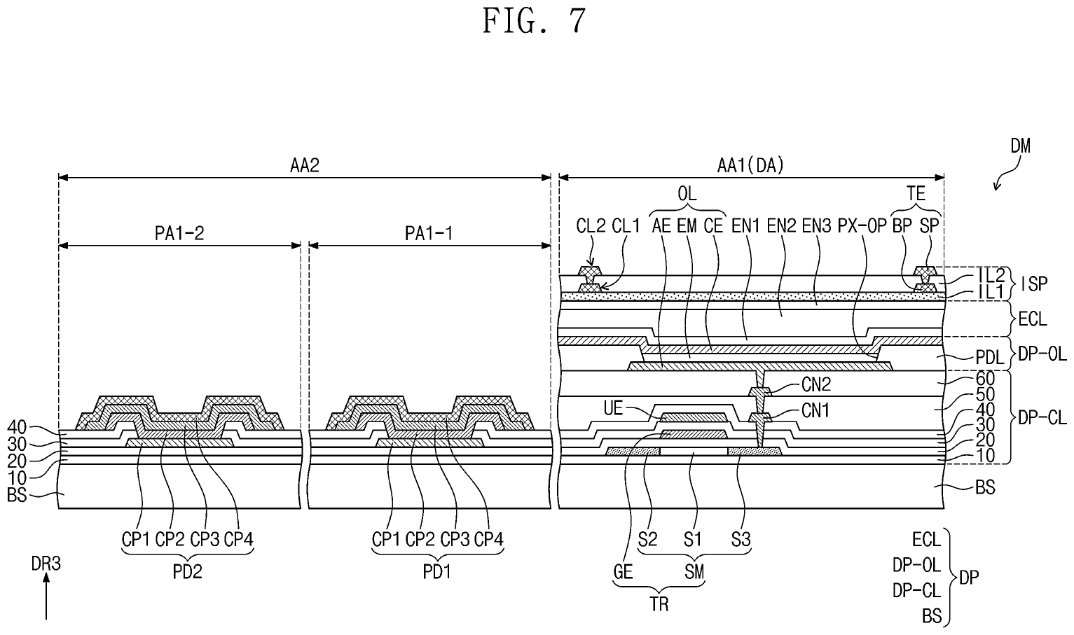

FIG. 7 is a cross-sectional view of a display module DM according to an embodiment of the inventive concept. More particularly, FIG. 7 exemplarily illustrates a cross-sectional of the pixel PX (see FIG. 4), disposed in a first base region AA1, and first signal pads PD1 and PD2, disposed in a second base region AA2, according to an embodiment of the inventive concept.

Referring to FIG. 7, the display module DM may include a display panel DP and an input sensor ISP disposed on the display panel DP. The previous description may be equally applied to each of the components.

Referring to FIG. 7, the display panel DP may include a base substrate BS, a circuit layer DP-CL, a display element layer DP-OL, and an encapsulation layer ECL.

The base substrate BS may be insulating, and may provide a base surface on which components of the display module DM are disposed. The base substrate BS may have flexibility to be bendable. As previously described, the base substrate BS may include a first base region AA1, a bending region BA (see FIG. 4), and a second base region AA2, and the bending region BA (see FIG. 4) of the base substrate BS may be bent to a predetermined curvature.

The circuit layer DP-CL may include insulation layers 10 to 60, a transistor TR of the pixel PX (see FIG. 4), an upper electrode UE, and connection electrodes CN1 and CN2, disposed on the base substrate BS. The insulation layers 10 to 60 may include first to sixth insulation layers 10 to 60 sequentially stacked on the base substrate BS along the thickness direction. However, an embodiment of the insulation layers 10 to 60 included in the circuit layer DP-CL is not necessarily limited thereto, and may be changed according to the configuration or manufacturing process of the circuit layer DP-CL.

The first insulation layer 10 may be disposed on the base substrate BS. The first insulation layer 10 may be provided as a barrier layer and/or a buffer layer that prevent foreign substances from being introduced from the outside. The first insulation layer 10 may increase coupling force between the base substrate BS and a semiconductor pattern SM and/or a conductive pattern of the circuit layer DP-CL. The first insulation layer 10 may include a silicon oxide layer and/or a silicon nitride layer. In an embodiment, the first insulation layer 10 may include the silicon oxide layers and the silicon nitride layers alternately stacked.

The pixel PX (see FIG. 4) may be disposed on the base substrate BS. The pixel PX (see FIG. 4) may be disposed in correspondence to a display region DA of the first base region AA1. The pixel PX (see FIG. 4) may include a transistor TR and a light-emitting element OL.

The transistor TR may include a semiconductor pattern SM and a gate electrode GE. The semiconductor pattern SM may be disposed on the first insulation layer 10. The semiconductor pattern SM may include a channel S1, a source S2, and a drain S3. The semiconductor pattern SM may include a silicon semiconductor, and include a single-crystal silicon semiconductor, a polysilicon semiconductor, or an amorphous silicon semiconductor. An embodiment of the inventive concept is not necessarily limited thereto, and the semiconductor pattern SM may also include an oxide semiconductor. The semiconductor pattern SM, according to an embodiment of the inventive concept, may be formed of various materials as long as having semiconductor properties, and is not necessarily limited to any one embodiment of the inventive concept.

The semiconductor pattern SM may include a plurality of regions having different electrical properties depending on whether it is doped or not, or reduced or not. For example, the semiconductor pattern SM may include a region which is doped or in which metal oxide is reduced, and which thus has high conductivity, and the region having high conductivity may serve as an electrode or a signal wire of the transistor TR. This may correspond to the source S2 and the drain S3 of the transistor TR. The semiconductor pattern SM may include a region which is undoped and thus has relatively low conductivity, and this may correspond to the channel S1 (or active) of the transistor TR.

The second insulation layer 20 may be disposed on the first insulation layer 10 and may cover the semiconductor pattern SM. The gate electrode GE may be disposed on the second insulation layer 20. The second insulation layer 20 may be disposed between the semiconductor pattern SM and the gate electrode GE of the transistor TR. The gate electrode GE may overlap the channel S1 of the semiconductor pattern SM in a plan view. The gate electrode GE may function as a mask in a doping process of the semiconductor pattern SM. The gate electrode GE may include molybdenum (Mo), a molybdenum-including alloy, titanium (Ti), a titanium-including alloy, etc. which have heat resistance, but an embodiment of the inventive concept is not necessarily limited thereto.

The structure of the transistor TR illustrated in FIG. 7 is an example, and the source S2 or the drain S3 of the transistor TR may also be electrodes formed independently of the semiconductor pattern SM. In this case, the source S2 and the drain S3 may be in contact with the semiconductor pattern SM, or pass through the insulation layer to be connected to the semiconductor pattern SM. In addition, the gate electrode GE may be disposed under the semiconductor pattern SM. The transistor TR, according to an embodiment of the inventive concept, may be formed in various structures, and is not necessarily limited to any one embodiment of the inventive concept.

The second insulation layer 20, and the third to sixth insulation layers 30 to 60 to be described later, may include at least one of an inorganic layer or an organic layer. For example, the inorganic layer may include aluminum oxide, titanium oxide, silicon oxide, silicon oxynitride, zirconium oxide, and/or hafnium oxide. The organic layer may include an acrylate-based resin, a methacrylate-based resin, polyisoprene, a vinyl-based resin, an epoxy-based resin, a urethane-based resin, a cellulose-based resin, a siloxane-based resin, a polyamide-based resin, and/or a perylene-based resin.

The third insulation layer 30 may be disposed on the second insulation layer 20 and may cover the gate electrode GE. An upper electrode UE may be disposed on the third insulation layer 30. The upper electrode UE may overlap the gate electrode GE in a plan view, and the gate electrode GE and the upper electrode UE overlapping each other may form a capacitor.

The fourth insulation layer 40 may be disposed on the third insulation layer 30 and may cover the upper electrode UE. The connection electrodes CN1 and CN2 may include a first connection electrode CN1 and a second connection electrode CN2. The first connection electrode CN1 may be disposed on the fourth insulation layer 40. The fifth insulation layer 50 may be disposed on the fourth insulation layer 40 to cover the first connection electrode CN1. The second connection electrode CN2 may be disposed on the fifth insulation layer 50. The sixth insulation layer 60 may be disposed on the fifth insulation layer 50 to cover the second connection electrode CN2. In an embodiment, at least any one of the fifth insulation layer 50 or the sixth insulation layer 60 may include an organic layer and may cover a step between components disposed thereunder to provide a flat upper surface.

The first connection electrode CN1 may be electrically connected to the semiconductor pattern SM through a contact hole passing through the second to fourth insulation layers 20 to 40. The second connection electrode CN2 may be electrically connected to the first connection electrode CN1 through a contact hole passing through the fifth insulation layer 50.

The first connection electrode CN1 and the second connection electrode CN2 may each include a conductive material. The first connection electrode CN1 and the second connection electrode CN2 may each include gold, silver, copper, aluminum, platinum, molybdenum, titanium, and/or an alloy thereof. At least any one of the first connection electrode CN1 or the second connection electrode CN2 may include conductive layers in a multi-layer structure. For example, at least any one of the first connection electrode CN1 or the second connection electrode CN2 may have a three-layer structure of titanium/aluminum/titanium. However, an embodiment of the inventive concept is not necessarily limited thereto.

According to an embodiment of the circuit layer DP-CL, at least any one of the first connection electrode CN1 or the second connection electrode CN2 may be omitted. Alternatively, according to an embodiment of the circuit layer DP-CL, an additional connection electrode that connects the transistor TR to the light-emitting element OL may further be disposed. According to the number of insulation layers disposed between the light-emitting element OL and the transistor TR, the electrical connection type between the light-emitting element OL and the transistor TR may be variously changed, and is not necessarily limited to any one embodiment of the inventive concept.

The display element layer DP-OL may include the light-emitting element OL and a pixel-defining film PDL. The light-emitting element OL and the pixel-defining film PDL may be disposed on the sixth insulation layer 60. The light-emitting element OL may include a first electrode AE, a light-emitting layer EM, and a second electrode CE.

The first electrode AE may be electrically connected to the second connection electrode CN2 through a contact hole passing through the sixth insulation layer 60. The first electrode AE may be electrically connected to the transistor TR through the first and second connection electrodes CN1 and CN2.

A pixel opening PX-OP that exposes at least a portion of the first electrode AE may be defined in the pixel-defining film PDL. One region of the first electrode AE exposed from the pixel-defining film PDL may correspond to a light-emitting region. The pixel-defining film PDL may include an inorganic layer, an organic layer, or a composite material layer. According to an embodiment, the pixel-defining film PDL may further include a black pigment or black dye.

The light-emitting layer EM may be disposed on the first electrode AE. The light-emitting layer EM may provide light of a predetermined color. The light-emitting layer EM may be disposed in correspondence to the pixel opening PX-OP defined in the pixel-defining film PDL. The light-emitting element OL and the pixel opening PX-OP may be provided in plurality, and the light-emitting layers EM of the light-emitting elements OL may be disposed respectively in correspondence to the pixel openings PX-OP, and provided in the form of patterns spaced apart from each other. However, an embodiment of the inventive concept is not necessarily limited thereto, and the light-emitting layers EM of the light-emitting elements OL may also be formed integrally as a common layer.

The second electrode CE may be disposed on the light-emitting layer EM and the pixel-defining film PDL. The second electrode CE may be provided as a common electrode that is disposed across the pixels PX (see FIG. 4) in common.

The light-emitting element OL may further include a hole control region, disposed between the first electrode AE and the light-emitting layer EM, and/or an electron control region disposed between the light-emitting layer EM and the second electrode CE. The hole control region may include a hole generation layer, a hole transport layer, and/or an electron-blocking layer, and the electron control region may include an electron generation layer, an electron transport layer, and/or a hole-blocking layer.

The encapsulation layer ECL may be disposed on the display element layer DP-OL. The encapsulation layer ECL may be disposed on the light-emitting element OL and the pixel-defining film PDL, and may thus seal the light-emitting element OL. The encapsulation layer ECL may include an inorganic film and/or an organic film. In this embodiment, the encapsulation layer ECL may include a first inorganic film EN1, a second inorganic film EN3, and an organic film EN2 disposed between the first and second inorganic films EN1 and EN3. However, the composition of the encapsulation layer ECL is not necessarily limited thereto as long as it is capable of sealing the light-emitting element OL.

The first inorganic film EN1 may be disposed on the second electrode CE, and the organic film EN2 and the second inorganic film EN3 may be disposed in sequence on the first inorganic film EN1 in the thickness direction of the display panel DP. The first and second inorganic films EN1 and EN3 may protect the light-emitting element OL from moisture or oxygen introduced from the outside. For example, the first and second inorganic films EN1 and EN3 may each include silicon nitride, silicon oxynitride, silicon oxide, titanium oxide, and/or aluminum oxide. However, the material of the first and second inorganic films EN1 and EN3 is not necessarily limited to the examples. The organic film EN2 may prevent foreign substances from being introduced to the light-emitting element OL, and cover a step of components disposed under the organic film EN2. For example, the organic film EN2 may include an acrylate-based organic material. However, the material of the organic film EN2 is not necessarily limited to the example.

The input sensor ISP may be disposed on the display panel DP. The input sensor ISP may include a base layer IL1, a first sensing insulation layer IL2, a first sensing conductive layer CL1, and a second sensing conductive layer CL2. The input sensor ISP may further include a second sensing insulation layer IL3 (see FIG. 3) as illustrated in FIG. 3. The previous description may be equally applied to each of the components.

The base layer IL1 may be in contact with the uppermost layer of the encapsulation layer ECL. For example, the base layer IL1 may be in contact with the second inorganic film EN3 of the encapsulation layer ECL. The base layer IL1 of the input sensor ISP may be directly formed on a base surface provided by the encapsulation layer ECL. However, an embodiment of the inventive concept is not necessarily limited thereto. According to an embodiment, the base layer IL1 may be omitted, and in this case, the first sensing conductive layer CL1 of the input sensor ISP may be in contact with the encapsulation layer ECL.

The first sensing conductive layer CL1 may be disposed on the base layer IL1, and the second sensing conductive layer CL2 may be disposed on the first sensing insulation layer IL2. The first sensing conductive layer CL1 and the second sensing conductive layer CL2 may form a sensing electrode TE. The sensing electrode TE may correspond to at least one of the first and second sensing electrodes TEX and TEY (see FIG. 5) previously described. For example, the first sensing conductive layer CL1 may include a connection pattern BP of the sensing electrode TE, and the second sensing conductive layer CL2 may include a sensing pattern SP of the sensing electrode TE. However, an embodiment of the inventive concept is not necessarily limited thereto, and the first sensing conductive layer CL1 may include the sensing pattern SP, and the second sensing conductive layer CL2 may include the connection pattern BP.

The connection pattern BP may correspond to the first connection pattern BP1 (see FIG. 5) or the second connection pattern BP2 (see FIG. 5) previously described, and the sensing pattern SP may correspond to the first sensing pattern SP1 (see FIG. 5) or the second sensing pattern SP2 (see FIG. 5) previously described. The connection pattern BP may be disposed on a different layer from the layer on which the sensing pattern SP is disposed, and may thus be connected to the sensing pattern SP through a contact hole passing through the first sensing insulation layer IL2. However, an embodiment of the inventive concept is not necessarily limited thereto, and the connection pattern BP and the sensing pattern SP may be disposed on the same layer to be integrally formed.

The sensing electrode TE may have a pattern in a mesh form, and may be disposed in correspondence to a region where the pixel-defining film PDL is disposed. However, an embodiment of the inventive concept is not necessarily limited thereto, the sensing electrode TE may be provided in a single form of pattern overlapping the light-emitting element OL, and in this case, the sensing electrode TE may include a transparent conductive material.

The first insulation layer 10 and the second insulation layer 20 may extend from the first base region AA1, on the base substrate BS, to be disposed in the second base region AA2. A (1-1)-th signal pad PD1 and a (1-2)-th signal pad PD2 may be disposed on the second insulation layer 20. The (1-1)-th signal pad PD1 may be disposed in a first sub pad region PA1-1, and the (1-2)-th signal pad PD2 may be disposed in a second sub pad region PA1-2. The (1-1)-th signal pad PD1 may be disposed closer to the display region DA in the first base region AA1 than the (1-2)-th signal pad PD2.

The first signal pads PD1 and PD2 may each include a plurality of conductive patterns CP1, CP2, CP3, and CP4 disposed along the thickness direction. First conductive patterns CP1 (or (1-1)-th conductive patterns) of the (1-1)-th signal pad PD1 and first conductive patterns CP1 (or (1-1)-th conductive patterns) of the (1-2)-th signal pad PD2 may be disposed on the second insulation layer 20.

The first conductive patterns CP1 of the (1-1)-th signal pad PD1 and the (1-2)-th signal pad PD2 may be formed through the same process as the process through which the gate electrode GE of the transistor TR is formed, and may include the same material as that of the gate electrode GE. For example, after a conductive layer is formed on the second insulation layer 20 through a deposition process such as sputtering or chemical vapor deposition, the conductive layer may be patterned to form the gate electrode GE and the first conductive patterns CP1 of the first signal pads PD1 and PD2. The first conductive patterns CP1 of the first signal pads PD1 and PD2 may be disposed on the same layer as the layer on which the gate electrode GE of the transistor TR is disposed, and may thus include the same material as that of the gate electrode GE.

The third insulation layer 30 and the fourth insulation layer 40 may extend from the first base region AA1 to be disposed on the second base region AA2. A through hole, which exposes an upper surface of each of the first conductive patterns CP1 of the (1-1)-th signal pad PD1 and the (1-2)-th signal pad PD2, may be defined in the third insulation layer 30 and the fourth insulation layer 40. The third insulation layer 30 and the fourth insulation layer 40 may be formed by being sequentially deposited onto the first base region AA1 and the second base region AA2 and then etched such that a portion of each of the upper surfaces of the first conductive patterns CP1 of the first signal pads PD1 and PD2 is exposed.

As described in FIG. 7, at least some among the insulation layers disposed in the first base region AA1 may be disposed on the second base region AA2, and the stacked structure of the insulation layers disposed on the second base region AA2 is not necessarily particularly limited to what is illustrated in the drawing.

Second conductive patterns CP2 (or (1-2)-th conductive patterns) of the (1-1)-th signal pad PD1 and second conductive patterns CP2 (or (1-2)-th conductive patterns) of the (1-2)-th signal pad PD2 may be respectively disposed on the exposed upper surfaces of the first conductive patterns CP1. The second conductive patterns CP2 may be respectively in contact with the first conductive patterns CP1. A portion of each of the second conductive patterns CP2 may be disposed on the fourth insulation layer 40. For example, the portion of each of the second conductive patterns CP2 may be disposed on the fourth insulation layer 40 while covering inner side surfaces of the third and fourth insulation layers 30 and 40 exposed by the through hole.

The second conductive patterns CP2 of the (1-1)-th signal pad PD1 and the (1-2)-th signal pad PD2 may be formed through the same process as the process through which at least one of the conductive electrodes in the circuit layer DP-CL is formed. For example, the second conductive patterns CP2 of the (1-1)-th signal pad PD1 and the (1-2)-th signal pad PD2 may be formed through the same process as the process through which the first connection electrode CN1 is formed, and may include the same material as that of the first connection electrode CN1. After a conductive layer is formed on the fourth insulation layer 40 through a deposition process such as sputtering or chemical vapor deposition, the conductive layer may be patterned to form the first connection electrode CN1 and the second conductive patterns CP2 of the first signal pads PD1 and PD2. The second conductive patterns CP2 of the first signal pads PD1 and PD2 may be disposed on the same layer as the layer on which the first connection electrode CN1 is disposed, and may include the same material as that of the first connection electrode CN1.

Third conductive patterns CP3 (or (1-3)-th conductive patterns) of the (1-1)-th signal pad PD1 and third conductive patterns CP3 (or (1-3)-th conductive patterns) of the (1-2)-th signal pad PD2 may be respectively disposed on the second conductive patterns CP2. The third conductive patterns CP3 may be respectively in contact with the second conductive patterns CP2. The third conductive patterns CP3 of the (1-1)-th signal pad PD1 and the (1-2)-th signal pad PD2 may be formed through the same process as the process through which at least one of the conductive electrodes in the circuit layer DP-CL is formed. For example, the third conductive patterns CP3 of the (1-1)-th signal pad PD1 and the (1-2)-th signal pad PD2 may be formed through the same process as the process through which the second connection electrode CN2 is formed, and may include the same material as that of the second connection electrode CN2. The fifth insulation layer 50 disposed under the second connection electrode CN2 may be opened in correspondence to a region where the first signal pads PD1 and PD2 are disposed. For example, the fifth insulation layer 50 might not be disposed on the second conductive patterns CP2 of the first signal pads PD1 and PD2, and a portion of a conductive layer deposited onto the fifth insulation layer 50 may be in contact with the second conductive patterns CP2. After the conductive layer is formed on the fifth insulation layer 50 through a deposition process such as sputtering or chemical vapor deposition, the conductive layer may be patterned to form the second connection electrode CN2 and the third conductive patterns CP3 of the first signal pads PD1 and PD2. The third conductive patterns CP3 may be disposed on the same layer as the layer on which the second connection electrode CN2 is disposed, and may include the same material as that of the second connection electrode CN2.

Fourth conductive patterns CP4 (or (1-4)-th conductive patterns) of the (1-1)-th signal pad PD1 and fourth conductive patterns CP4 (or (1-4)-th conductive patterns) of the (1-2)-th signal pad PD2 may be respectively disposed on upper surfaces of the third conductive patterns CP3. The fourth conductive patterns CP4 may be respectively in contact with the third conductive patterns CP3.

The fourth conductive patterns CP4 of the (1-1)-th signal pad PD1 and the (1-2)-th signal pad PD2 may be formed through the same process as the process through which at least one of the conductive layers of the input sensor ISP is formed. For example, the fourth conductive patterns CP4 of the (1-1)-th signal pad PD1 and the (1-2)-th signal pad PD2 may be formed through the same process as the process through which the second sensing conductive layer CL2 is formed, and may include the same material as that of the second sensing conductive layer CL2. The fourth conductive patterns CP4 may include the same material as that of the first sensing conductive layer CL1 or the second sensing conductive layer CL2. The first conductive patterns CP1 to fourth conductive patterns CP4 may be electrically connected.

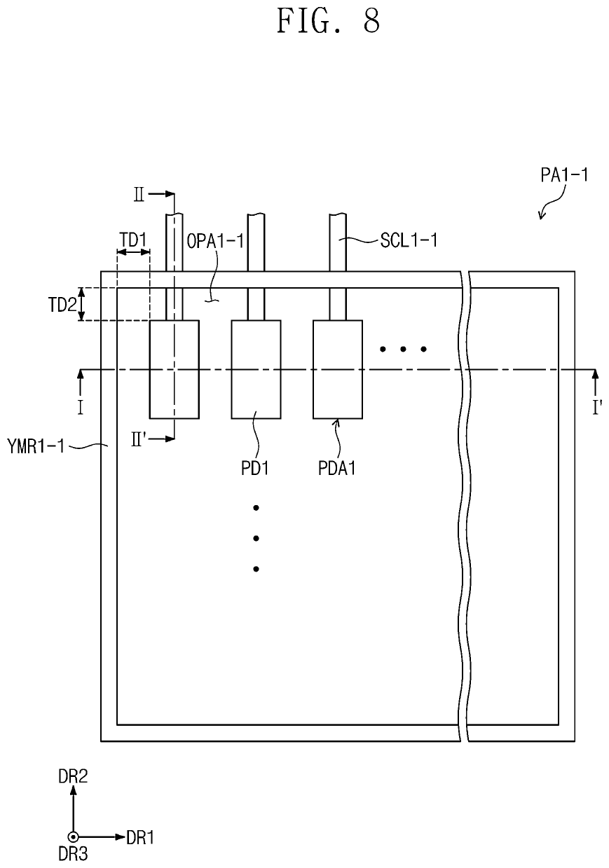

FIG. 8 is an enlarged plan view of a display module DM according to an embodiment of the inventive concept. More particularly, FIG. 8 is an enlarged plan view of a first sub pad region PA1-1 according to an embodiment of the inventive concept.

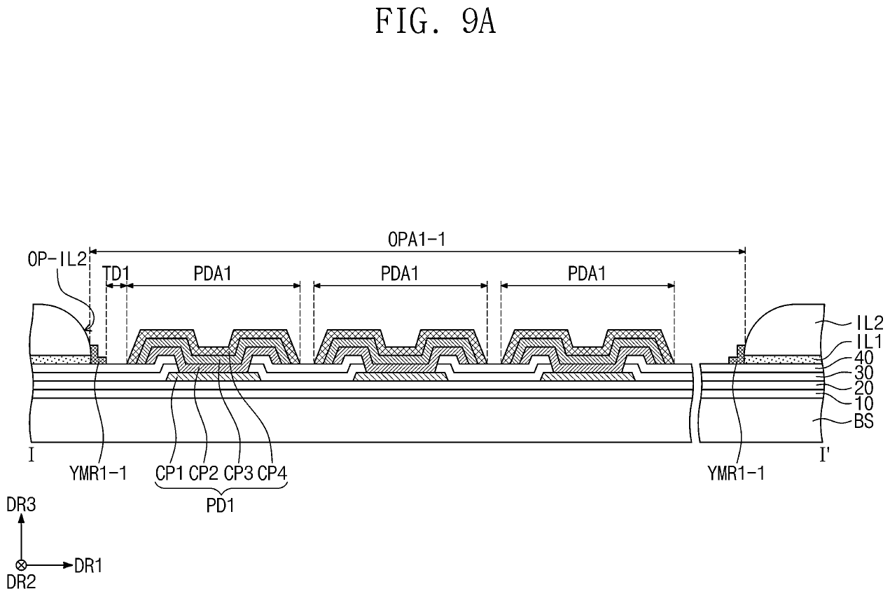

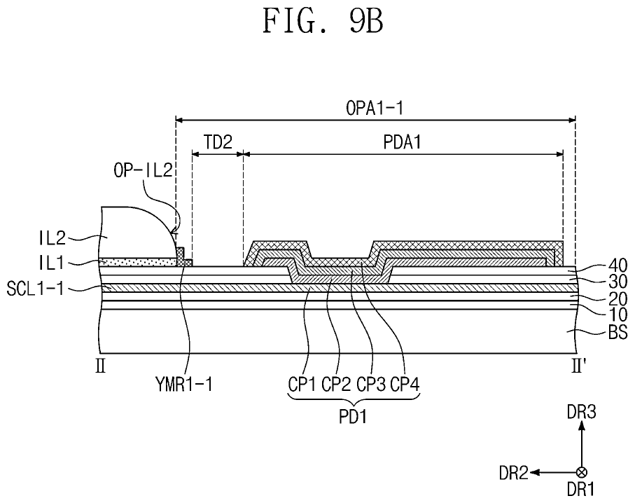

Referring to FIG. 8, a plurality of (1-1)-th signal pads PD1 may be disposed in the first sub pad region PA1-1. The first sub pad region PA1-1 may include a (1-1)-th signal pad region PDA corresponding to the (1-1)-th signal pads PD1. The first sub pad region PA1-1 may include a (1-1)-th opening region OPA1-1 corresponding to an opening OP-IL2 (see FIG. 9A) formed on a first sensing insulation layer IL2 (see FIG. 9A). The (1-1)-th opening region OPA1-1 may overlap the (1-1)-th signal pad region PDA1. The (1-1)-th opening region OPA1-1 will be described later with reference to FIG. 9A.

The (1-1)-th signal pads PD1 may be disposed in plurality inside a (1-1)-th residue conductive pattern YMR1-1. The (1-1)-th signal pads PD1 may include a plurality of pad rows, and the plurality of pad rows may be arranged along a second direction DR2. Here, the (1-1)-th signal pads PD1 are schematically illustrated to have a rectangular shape extending in the second direction DR2, but the shape of the (1-1)-th signal pads PD1 is not necessarily limited thereto.

The (1-1)-th signal pads PD1 may be electrically connected to the pixels PX (see FIG. 4) through (1-1)-th signal lines SCL1-1. The (1-1)-th signal lines SCL1-1 may cross the (1-1)-th residue conductive pattern YMR1-1 in a plan view while electrically insulated therefrom.

The (1-1)-th residue conductive pattern YMR1-1 may be disposed on a border of the (1-1)-th opening region OPA1-1. The (1-1)-th residue conductive pattern YMR1-1 may be spaced apart from the (1-1)-th signal pads PD1 by a predetermined distance in a plan view. The (1-1)-th residue conductive pattern YMR1-1 might not overlap the (1-1)-th signal pads PD1 in a plan view.

The minimum distance between the (1-1)-th residue conductive pattern YMR1-1 and the (1-1)-th signal pads PD1 may be about 20 μm or more. When the minimum distance between the (1-1)-th residue conductive pattern YMR1-1 and the (1-1)-th signal pads PD1 is less than about 20 μm, a short circuit may occur between the (1-1)-th residue conductive pattern YMR1-1 and the (1-1)-th signal pads PD1.

A minimum distance TD1 between the (1-1)-th residue conductive pattern YMR1-1 and the (1-1)-th signal pads PD1 in a first direction DR1 may be about 20 μm or more. A minimum distance TD2 between the (1-1)-th residue conductive pattern YMR1-1 and the (1-1)-th signal pads PD1 in a second direction DR2 may be about 20 μm or more.

FIG. 9A is a cross-sectional view taken along line I-I′ of FIG. 8 according to an embodiment of the inventive concept.

Referring to FIG. 9A, a plurality of (1-1)-th signal pads PD1 may be arranged along a first direction DR1. The adjacent (1-1)-th signal pads PD1 may be spaced apart from each other by a predetermined distance to thereby prevent a short circuit between the plurality of (1-1)-th signal pads PD1. The (1-1)-th signal pads PD1 and a (1-1)-th residue conductive pattern YMR1-1 may be spaced apart from each other by a predetermined distance TD1 along the first direction DR1. Accordingly, a short circuit between the (1-1)-th residue conductive pattern YMR1-1 and the (1-1)-th signal pads PD1 may be prevented.

An insulation opening OP-IL2 (or first opening) overlapping the first sub pad region PA1-1 (see FIG. 8) may be defined in a first sensing insulation layer IL2. The insulation opening OP-IL2 may entirely overlap a plurality of (1-1)-th signal pad regions PDA1. An inner side surface of the first sensing insulation layer IL2 defining the insulation opening OP-IL2 may be spaced apart from the (1-1)-th signal pad region PDA1 by a predetermined distance. The first sensing insulation layer IL2 might not be in contact with the (1-1)-th signal pads PD1. The first sensing insulation layer IL2 might not overlap the (1-1)-th signal pads PD1.

Since the first sensing insulation layer IL2 does not overlap the (1-1)-th signal pads PD1, it may be possible to solve problems which might occur in the (1-1)-th signal pads PD1 due to the first sensing insulation layer IL2.

For example, in a case where the first sensing insulation layer IL2 overlaps the (1-1)-th signal pads PD1, a portion of the first sensing insulation layer IL2 may overlap the (1-1)-th signal pad region PDA1, and fourth conductive patterns CP4 may be disposed on the portion of the first sensing insulation layer IL2. At this time, in a case where the first sensing insulation layer IL2 is an organic film including an organic material, the first sensing insulation layer IL2 may be deformed when pressure is applied to the first sensing insulation layer IL2. In case of performing pressing for bonding between the data driver DDV (see FIG. 6) and the (1-1)-th signal pads PD1, the first sensing insulation layer IL2 may be deformed due to the pressure. Accordingly, the fourth conductive patterns CP4 disposed on the first sensing insulation layer IL2 may be deformed, thereby causing cracks on the fourth conductive patterns CP4.

In addition, since the first sensing insulation layer IL2 includes an organic material that is relatively high in moisture permeability, moisture may be supplied to a conductive layer disposed on the first sensing insulation layer IL2, which is provided for forming the fourth conductive patterns CP4. Accordingly, a portion of the conductive layer may be oxidized. For the oxidized conductive layer, etching might not be performed smoothly in an etching process of forming the fourth conductive patterns CP4. Accordingly, the fourth conductive patterns CP4 might not be formed properly, and a short circuit may occur between the adjacent (1-1)-th signal pads PD1 due to the unetched conductive layer. Since the first sensing insulation layer IL2 does not overlap the (1-1)-th signal pads PD1, it may be possible to solve the above-mentioned problems.

An opening corresponding to the insulation opening OP-IL2 may be defined also in a base layer IL1. An end of the base layer IL1 and an end of the first sensing insulation layer IL2 may be formed on the same position in the first direction DR1.

The (1-1)-th residue conductive pattern YMR1-1, including the same material as that of the second sensing conductive layer CL2 (see FIG. 7), may be defined on a border of the insulation opening OP-IL2. The (1-1)-th residue conductive pattern YMR1-1 may include the same material as that of the fourth conductive patterns CP4. The (1-1)-th residue conductive pattern YMR1-1 may be formed from the same conductive layer as the conductive layer from which the fourth conductive patterns CP4 are formed. For example, the (1-1)-th residue conductive pattern YMR1-1 may be a portion that remains unetched in the etching process of forming the fourth conductive patterns CP4 after forming of the conductive layer.

Since the (1-1)-th residue conductive pattern YMR1-1 is spaced apart from the (1-1)-th signal pads PD1 by the predetermined distance TD1, it may be possible to prevent a short circuit caused by the contact between the (1-1)-th residue conductive pattern YMR1-1 and the fourth conductive patterns CP4 of the (1-1)-th signal pads PD1.

FIG. 9B is a cross-sectional view taken along line II-II′ of FIG. 8 according to an embodiment of the inventive concept.

Referring to FIG. 9B, (1-1)-th signal lines SCL1-1 may be disposed on the same layer as the layer on which first conductive patterns CP1 of (1-1)-th signal pads PD1 are disposed, and include the same material as that of the first conductive patterns CP1 of the (1-1)-th signal pads PD1. The (1-1)-th signal lines SCL1-1 may be disposed on the same layer as the layer on which the gate electrode GE (see FIG. 7) is disposed, and include the same material as that of the gate electrode GE. The (1-1)-th signal lines SCL1-1 may overlap a (1-1)-th residue conductive pattern YMR1-1. Insulation layers 30 and 40 may be disposed between the (1-1)-th signal lines SCL1-1 and the (1-1)-th residue conductive pattern YMR1-1. The insulation layers 30 and 40 disposed between the (1-1)-th signal lines SCL1-1 and the (1-1)-th residue conductive pattern YMR1-1 may include the same material as that of a third insulation layer 30 and a fourth insulation layer 40 disposed between a transistor TR and a light-emitting element OL. Accordingly, it may be possible to prevent the (1-1)-th signal lines SCL1-1 and the (1-1)-th residue conductive pattern YMR1-1, crossing each other in a plan view, from being electrically connected.

The (1-1)-th residue conductive pattern YMR1-1 may be spaced apart from the (1-1)-th signal pads PD1 by a predetermined distance TD2. Accordingly, the (1-1)-th residue conductive pattern YMR1-1 and the (1-1)-th signal pads PD1 may be electrically insulated from each other.

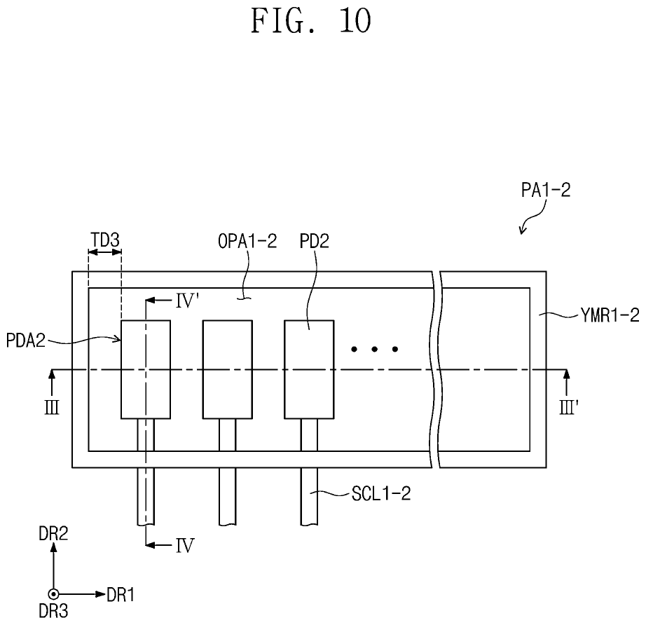

FIG. 10 is an enlarged plan view of a display module according to an embodiment of the inventive concept. More particularly, FIG. 10 is an enlarged plan view of a second sub pad region PA1-2 according to an embodiment of the inventive concept.

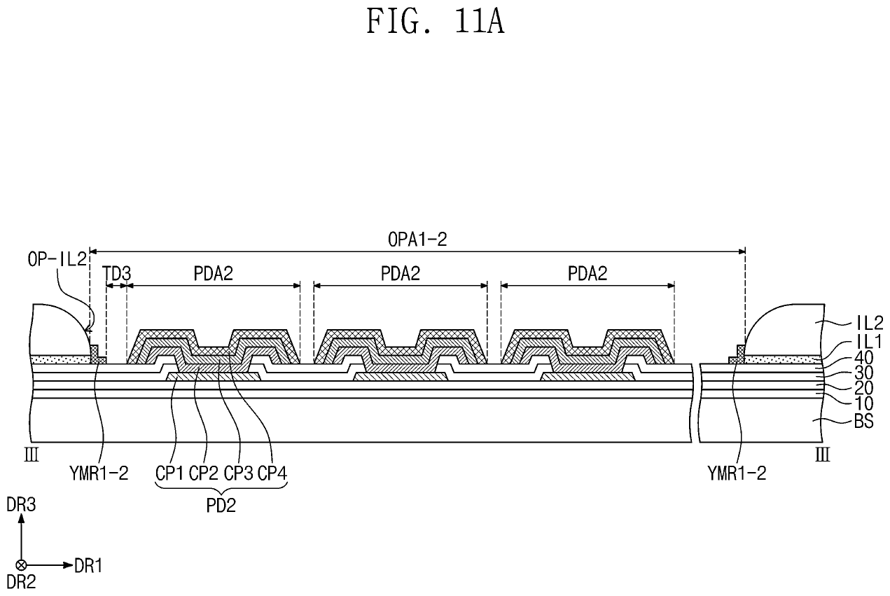

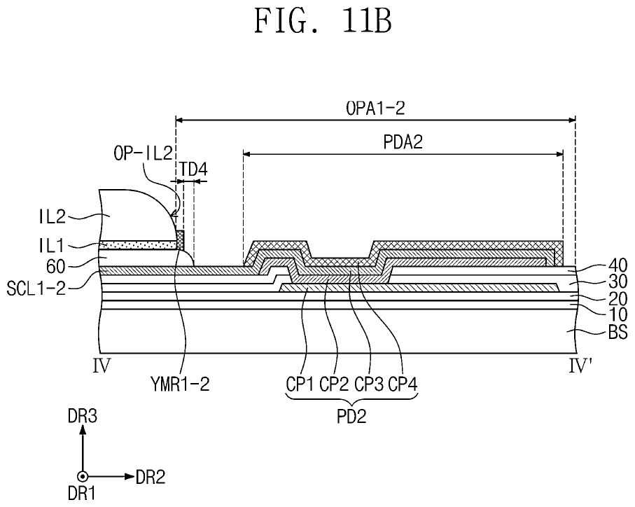

Referring to FIG. 10, a plurality of (1-2)-th signal pads PD2 may be disposed in the second sub pad region PA1-2. The second sub pad region PA1-2 may include a (1-2)-th signal pad region PDA2 corresponding to the (1-2)-th signal pads PD2. The second sub pad region PA1-2 may include a (1-2)-th opening region OPA1-2 corresponding to an opening OP-IL2 (see FIG. 11A) formed in a first sensing insulation layer IL2 (see FIG. 11A). The (1-2)-th opening region OPA1-2 may overlap the (1-2)-th signal pad region PDA2. The (1-2)-th opening region OPA1-2 will be described later with reference to FIG. 11A.

The (1-2)-th signal pads PD2 may be disposed in plurality inside the (1-2)-th residue conductive pattern YMR1-2. The (1-2)-th signal pads PD2 may be arranged in a first direction DR1. Here, the (1-2)-th signal pads PD2 are schematically illustrated to have a rectangular shape extending in a second direction DR2, but the shape of the (1-2)-th signal pads PD2 is not necessarily limited thereto.

The (1-2)-th signal pads PD2 may be electrically connected to the pixels PX (see FIG. 4) and corresponding display pads D-PD (see FIG. 6) through (1-2)-th signal lines SCL1-2. The (1-2)-th signal lines SCL1-2 may cross the (1-2)-th residue conductive pattern YMR1-2 in a plan view while electrically insulated therefrom.

The (1-2)-th residue conductive pattern YMR1-2 may be disposed on a border of the (1-2)-th opening region OPA1-2. The (1-2)-th residue conductive pattern YMR1-2 may be spaced apart from the (1-2)-th signal pads PD2 by a predetermined distance in a plan view. The (1-2)-th residue conductive pattern YMR1-2 might not overlap the (1-2)-th signal pads PD2 in a plan view.

The minimum distance between the (1-2)-th residue conductive pattern YMR1-2 and the (1-2)-th signal pads PD2 may be about 20 μm or more. When the minimum distance between the (1-2)-th residue conductive pattern YMR1-2 and the (1-2)-th signal pads PD2 is less than about 20 μm, a short circuit may occur between the (1-2)-th residue conductive pattern YMR1-2 and the (1-2)-th signal pads PD2.

A minimum distance TD3 between the (1-2)-th residue conductive pattern YMR1-2 and the (1-2)-th signal pads PD2 in the first direction DR1 may be about 20 μm or more.

FIG. 11A is a cross-sectional view taken along line III-III′ of FIG. 10 according to an embodiment of the inventive concept.

Referring to FIG. 11A, a plurality of (1-2)-th signal pads PD2 may be arranged along a first direction DR1. The plurality of (1-2)-th signal pads PD2 may be spaced apart from each other by a predetermined distance to thereby prevent a short circuit between the plurality of (1-2)-th signal pads PD2. The (1-2)-th signal pads PD2 and a (1-2)-th residue conductive pattern YMR1-2 may be spaced apart from each other by a predetermined distance TD3 along the first direction DR1.

An insulation opening OP-IL2 (or second opening) overlapping a second sub pad region PA1-2 (see FIG. 10) may be defined in a first sensing insulation layer IL2. The insulation opening OP-IL2 may entirely overlap a plurality of (1-2)-th signal pad regions PDA2. An inner side surface of the first sensing insulation layer IL2 defining the insulation opening OP-IL2 may be spaced apart from the (1-2)-th signal pad region PDA2 by a predetermined distance. The first sensing insulation layer IL2 might not be in contact with the (1-2)-th signal pads PD2. The first sensing insulation layer IL2 might not overlap the (1-2)-th signal pads PD2.

An opening corresponding to the insulation opening OP-IL2 may be defined also in a base layer IL1. An end of the base layer IL1 and an end of the first sensing insulation layer IL2 may be formed on the same position in the first direction DR1.

The (1-2)-th residue conductive pattern YMR1-2 including the same material as that of the second sensing conductive layer CL2 (see FIG. 7) may be defined on a border of the insulation opening OP-IL2. The (1-2)-th residue conductive pattern YMR1-2 may include the same material as that of fourth conductive patterns CP4. The (1-2)-th residue conductive pattern YMR1-2 may be formed from the same conductive layer as the conductive layer from which the fourth conductive patterns CP4 are formed. The (1-2)-th residue conductive pattern YMR1-2 may be a portion which remains unetched in an etching process of forming the fourth conductive patterns CP4 after forming of the conductive layer.

Since the (1-2)-th residue conductive pattern YMR1-2 is spaced apart from the (1-2)-th signal pads PD2 by the predetermined distance TD3, it may be possible to prevent a short circuit caused by the contact between the (1-2)-th residue conductive pattern YMR1-2 and the fourth conductive patterns CP4 of the (1-2)-th signal pads PD2.

FIG. 11B is a cross-sectional view taken along line IV-IV′ of FIG. 10 according to an embodiment of the inventive concept.

Referring to FIG. 11B, (1-2)-th signal lines SCL1-2 may be disposed on the same layer as the layer on which third conductive patterns CP3 of (1-2)-th signal pads PD2 are disposed, and include the same material as that of the third conductive patterns CP3 of the (1-2)-th signal pads PD2. The (1-2)-th signal lines SCL1-2 may be disposed on the same layer as the layer on which the second connection electrode CN2 (see FIG. 7) is disposed, and include the same material as that of the second connection electrode CN2. The (1-2)-th signal lines SCL1-2 may overlap a (1-2)-th residue conductive pattern YMR1-2. A sixth insulation layer 60 may be disposed between the (1-2)-th signal lines SCL1-2 and the (1-2)-th residue conductive pattern YMR1-2. Accordingly, it may be possible to prevent the (1-2)-th signal lines SCL1-2 and the (1-2)-th residue conductive pattern YMR1-2, crossing each other in a plan view, from being electrically connected.

The (1-2)-th residue conductive pattern YMR1-2 may be disposed on the sixth insulation layer 60. The (1-2)-th residue conductive pattern YMR1-2 may be spaced apart from an end of the sixth insulation layer 60 in a plan view by a predetermined distance TD4. The distance TD4 between the (1-2)-th residue conductive pattern YMR1-2 and the sixth insulation layer 60 in a plan view may be about 20 μm or more. When the distance TD4 between the (1-2)-th residue conductive pattern YMR1-2 and the sixth insulation layer 60 in a plan view is less than about 20 μm, the (1-2)-th residue conductive pattern YMR1-2 may become close to the (1-2)-th signal line SCL1-2 disposed under the sixth insulation layer 60. Accordingly, it may be increasingly possible that the (1-2)-th residue conductive pattern YMR1-2 and the (1-2)-th signal line SCL1-2 are electrically connected to each other, so that a short circuit occurs therebetween. Therefore, it may be desirable that the distance TD4 between the (1-2)-th residue conductive pattern YMR1-2 and the sixth insulation layer 60 is about 20 μm or more in a plan view.

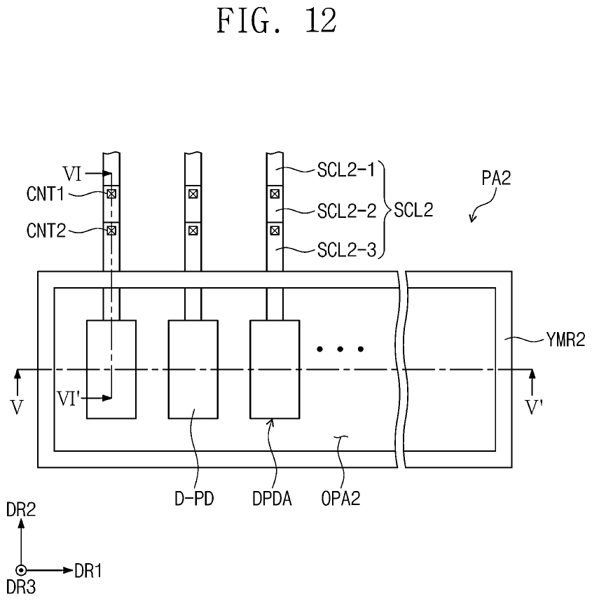

FIG. 12 is an enlarged plan view of a display module according to an embodiment of the inventive concept. More particularly, FIG. 12 is an enlarged plan view of a second pad region PA2 according to an embodiment of the inventive concept.

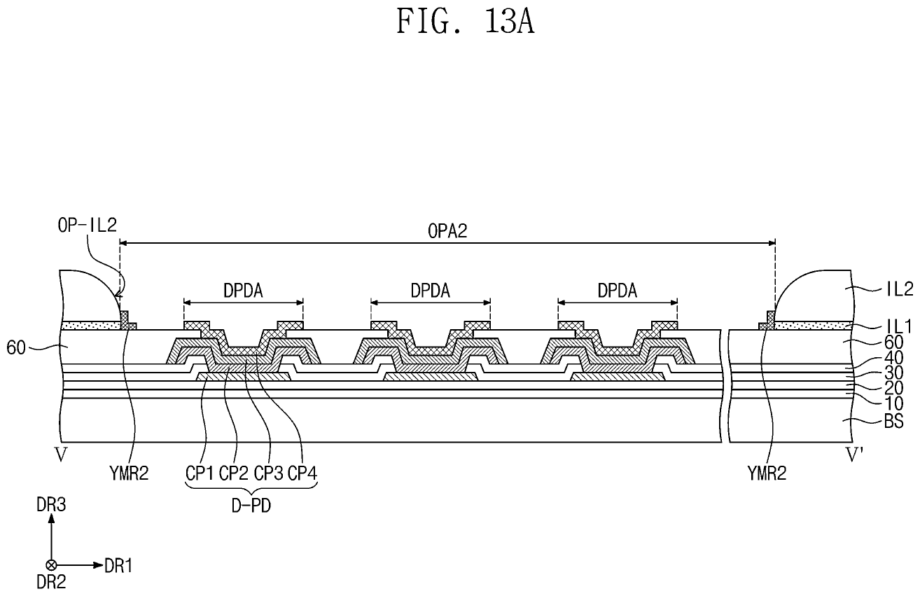

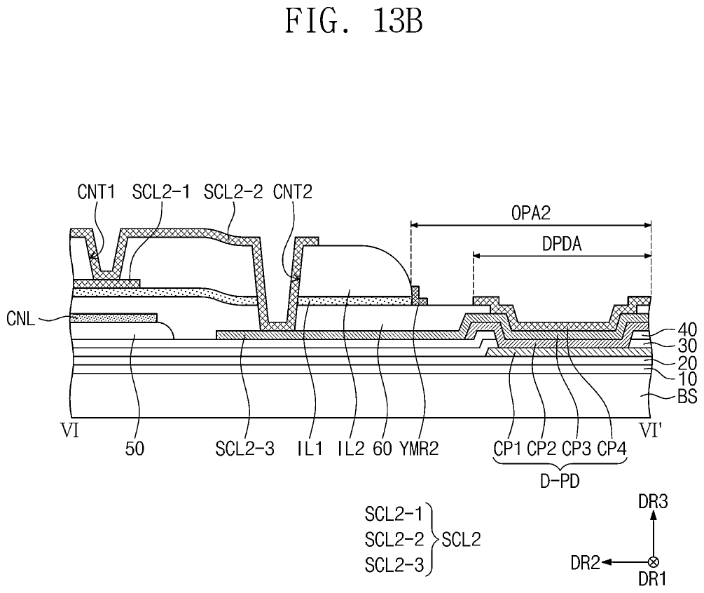

Referring to FIG. 12, a plurality of display pads D-PD may be disposed in the second pad region PA2. The second pad region PA2 may include a display pad region DPDA corresponding to the display pads D-PD. The second pad region PA2 may include a second opening region OPA2 corresponding to an opening OP-IL2 (see FIG. 13A) formed in a first sensing insulation layer IL2 (see FIG. 13A). The second opening region OPA2 may overlap the second pad region PDA2.

The display pads D-PD may be disposed further apart from the display region DA (see FIG. 4) than the first signal pads PD1 and PD2 (see FIG. 6). The display pads D-PD may be disposed in plurality inside a second residue conductive pattern YMR2. The display pads D-PD may be electrically connected to the pixels PX (see FIG. 4) through second signal lines SCL2-1, SCL2-2, and SCL2-3. The second signal lines SCL2 may include (2-1)-th signal lines SCL2-1, (2-2)-th signal lines SCL2-2, and (2-3)-th signal lines SCL2-3. The (2-1)-th signal lines SCL2-1 may be disposed on a different layer from the layer on which the (2-2)-th signal lines SCL2-2 are disposed. The (2-1)-th signal lines SCL2-1 may be connected to the (2-2)-th signal lines SCL2-2 by a first contact hole CNT1. The (2-2)-th signal lines SCL2-2 may be disposed on a different layer from the layer on which the (2-3)-th signal lines SCL2-3 are disposed. The (2-2)-th signal lines SCL2-2 may be connected to the (2-3)-th signal lines SCL2-3 by a second contact hole CNT2. The (2-3)-th signal lines SCL2-3 may electrically connect between the display pads D-PD and the (2-2)-th signal lines SCL2-2. The (2-3)-th signal lines SCL2-3 may cross the second residue conductive pattern YMR2 in a plan view while electrically insulated therefrom.

The second residue conductive pattern YMR2 may be disposed on a border of the second opening region OPA2. The second residue conductive pattern YMR2 may be spaced apart from the display pads D-PD in a plan view by a predetermined distance. The second residue conductive pattern YMR2 might not overlap the display pads D-PD in a plan view.

The minimum distance between the second residue conductive pattern YMR2 and the display pads D-PD may be about 20 μm or more. When the minimum distance between the second residue conductive pattern YMR2 and the display pads D-PD is less than about 20 μm, a short circuit may occur between the second residue conductive pattern YMR2 and the display pads D-PD.

FIG. 13A is a cross-sectional view taken along line V-V′ of FIG. 12 according to an embodiment of the inventive concept.

Referring to FIG. 13A, a plurality of display pads D-PD may be arranged along a first direction DR1. The plurality of display pads D-PD may be spaced apart from each other by a predetermined distance, thereby preventing a short circuit between the plurality of display pads D-PD. The display pads D-PD and a second residue conductive pattern YMR2 may be spaced apart from each other by a predetermined distance along the first direction DR1.

The display pads D-PD may include a plurality of conductive patterns CP1, CP2, CP3, and CP4 stacked along the thickness direction of the display panel DP (see FIG. 7). First conductive patterns CP1 of the display pads D-PD may be disposed on a second insulation layer 20. The first conductive patterns CP1 of the display pads D-PD may be formed through the same process as the process through which the gate electrode GE (see FIG. 7) of the transistor TR (see FIG. 7) is formed, and include the same material as that of the gate electrode GE. Second conductive patterns CP2 of the display pads D-PD may be formed through the same process as the process through which the first connection electrode CN1 (see FIG. 7) is formed, and include the same material as that of the first connection electrode CN1. Third conductive patterns CP3 of the display pads D-PD may be formed through the same process as the process through which the second connection electrode CN2 (see FIG. 7) is formed, and include the same material as that of the second connection electrode CN2. Fourth conductive patterns CP4 of the display pads D-PD may be formed through the same process as the process through which the second sensing conductive layer CL2 (see FIG. 7) is formed, and include the same material as that of the second sensing conductive layer CL2.

A sixth insulation layer 60 may be disposed on a fourth insulation layer 40. The sixth insulation layer 60 may be in contact with a portion of an upper surface of the third conductive pattern CP3, and may be in contact with a portion of a lower surface of the fourth conductive pattern CP4. Except for a portion of the sixth insulation layer 60 overlapping a display pad region DPDA, the sixth insulation layer 60 may provide a flat upper surface. A base layer IL1, a first sensing insulation layer IL2, and the second residue conductive pattern YMR2 may be disposed on the sixth insulation layer 60.

The sixth insulation layer 60 may include an organic material. Since the sixth insulation layer 60 includes the organic material relatively high in moisture permeability, moisture may be supplied to a conductive layer disposed on the sixth insulation layer 60, which is provided for forming the fourth conductive patterns CP4. Accordingly, a portion of the conductive layer may be oxidized. For the oxidized conductive layer, etching might not be performed smoothly in an etching process of forming the fourth conductive patterns CP4. Accordingly, the adjacent display pads D-PD may be connected due to the unetched conductive layer, thereby causing a short circuit therebetween. To prevent this, the minimum distance between the display pads D-PD may be about 10 μm or more.

An insulation opening OP-IL2 (or second opening) overlapping a second pad region PA2 (see FIG. 12) may be defined in the first sensing insulation layer IL2. The insulation opening OP-IL2 may entirely overlap a plurality of display pad regions DPDA. An inner side surface of the first sensing insulation layer IL2 defining the insulation opening OP-IL2 may be spaced apart from the display pad regions DPDA by a predetermined distance. The first sensing insulation layer IL2 might not be in contact with the display pads D-PD. The first sensing insulation layer IL2 might not overlap the display pads D-PD.

An opening corresponding to the insulation opening OP-IL2 may be defined also in the base layer IL1. An end of the base layer IL1 and an end of the first sensing insulation layer IL2 may be formed on the same position in the first direction DR1.

The second residue conductive pattern YMR2 including the same material as that of the second sensing conductive layer CL2 (see FIG. 7) may be defined on a border of the insulation opening OP-IL2. The second residue conductive pattern YMR2 may include the same material as that of the fourth conductive patterns CP4.

Since the second residue conductive pattern YMR2 may be spaced apart from the display pads D-PD by a predetermined distance, it may be possible to prevent a short circuit caused by the contact between the second residue conductive pattern YMR2 and the fourth conductive patterns CP4 of the display pads PD2.

FIG. 13B is a cross-sectional view taken along line VI-VI′ of FIG. 12 according to an embodiment of the inventive concept.

Referring to FIG. 13B, a conductive layer CNL may be disposed on a fifth insulation layer 50. The conductive layer CNL may be a voltage line that transmits a low driving voltage ELVSS. A (2-1)-th signal line SCL2-1 may include the same material as that of the first sensing conductive layer CL1 (see FIG. 7). A (2-2)-th signal line SCL2-2 may include the same material as that of the second sensing conductive layer CL2 (see FIG. 7). A (2-3)-th signal line SCL2-3 may include the same material as that of the second connection electrode CN2 (see FIG. 7).

The (2-2)-th signal line SCL2-2 may be electrically connected to the (2-1)-th signal line SCL2-1 by a first contact hole CNT1 passing through a first sensing insulation layer IL2. The (2-3)-th signal line SCL2-3 may be electrically connected to the (2-2)-th signal line SCL2-2 by a second contact hole CNT2 passing through the first sensing insulation layer IL2, a base layer IL1, and a sixth insulation layer 60. The (2-3)-th signal line SCL2-3 may be electrically connected to a third conductive pattern CP3 of each of display pads D-PD.

The (2-3)-th signal line SCL2-3 may overlap a second residue conductive pattern YMR2. The sixth insulation layer 60 may be disposed between the (2-3)-th signal line SCL2-3 and the second residue conductive pattern YMR2. Accordingly, it may be possible to prevent the (2-3)-th signal line SCL2-3 and the second residue conductive pattern YMR2, crossing each other in a plan view, from being electrically connected.

The second residue conductive pattern YMR2 may be spaced apart from the display pads D-PD by a predetermined distance, and thus electrically insulated therefrom.

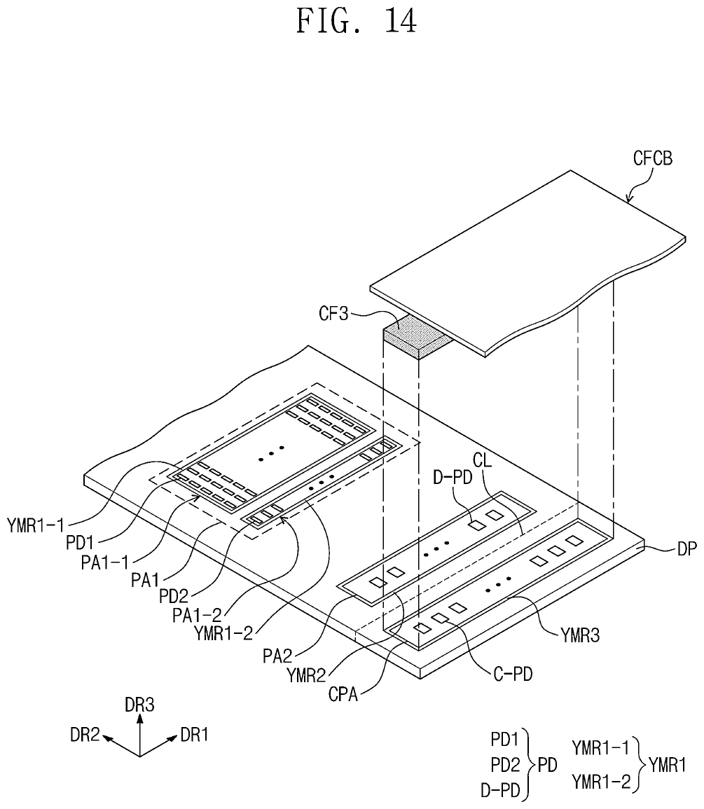

FIG. 14 is a perspective view of an electronic apparatus according to an embodiment of the inventive concept.

Referring to FIG. 14, a display panel before completion may further include test pads C-PD disposed further apart from the display region DA (see FIG. 4) than display pads D-PD, and electrically connected to the pixels PX (see FIG. 4). The test pads C-PD may be disposed in a test pad region CPA (or third pad region) which is disposed further apart from the display region DA (see FIG. 4) than a second pad region PDA2.

A test circuit board CFCB may be bonded to the test pad region CPA through a third conductive adhesive layer CF3. The third conductive adhesive layer CF3 may be provided as an anisotropy conductive adhesive. The test circuit board CFCB and the test pads C-PD connected to the test circuit board CFCB may be used for testing the pixel for defects. The test pads C-PD may be removed later through a cutting process. By removing the test pad region CPA positioned under a cutting line CL, the area of the non-display region NDA (see FIG. 4) may be reduced.

A third residue conductive pattern YMR3 may at least partially surround the test pad region CPA. The third residue conductive pattern YMR3 may be spaced apart from the test pads C-PD in a plan view. The third residue conductive pattern YMR3 may include a first part extending in a first direction DR1 and a second part extending in a second direction DR2. The third residue conductive pattern YMR3 may have a quadrilateral shape defined as the first part and the second part. The test pads C-PD may be disposed inside the third residue conductive pattern YMR3. FIG. 14 illustrates the third residue conductive pattern YMR2 as a quadrilateral shape, but this is an example, and the shape of the third residue conductive pattern YMR3 may be changed as necessary.

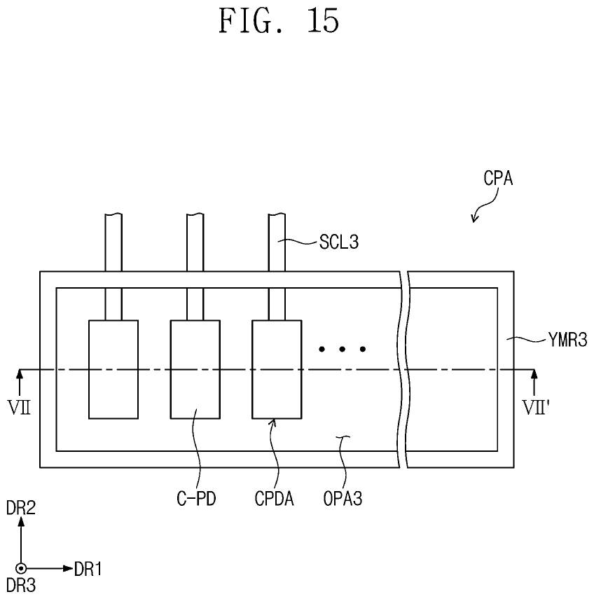

FIG. 15 is an enlarged plan view of a display module according to an embodiment of the inventive concept. More particularly, FIG. 15 is an enlarged plan view of a test pad region CPA according to an embodiment of the inventive concept.

Referring to FIG. 15, a plurality of test pads C-PD may be disposed in the test pad region CPA. The test pad region CPA may include a sub test pad region CPDA corresponding to the test pads C-PD. The test pad region CPA may include a third opening region OPA3 corresponding to the opening OP-IL2 (see FIG. 9A) formed in the first sensing insulation layer IL2 (see FIG. 9A). The third opening region OPA3 may overlap the test pad region CPA.

The test pads C-PD may be electrically connected to the pixels PX (see FIG. 4) through third signal lines SCL3. The third signal lines SCL3 may cross a third residue conductive pattern YMR3 in a plan view while electrically insulated therefrom.

The third residue conductive pattern YMR3 may be disposed on a border of the third opening region OPA3. The third residue conductive pattern YMR3 may be spaced apart from the test pads C-PD in a plan view by a predetermined distance. The third residue conductive pattern YMR3 might not overlap the test pads C-PD in a plan view.

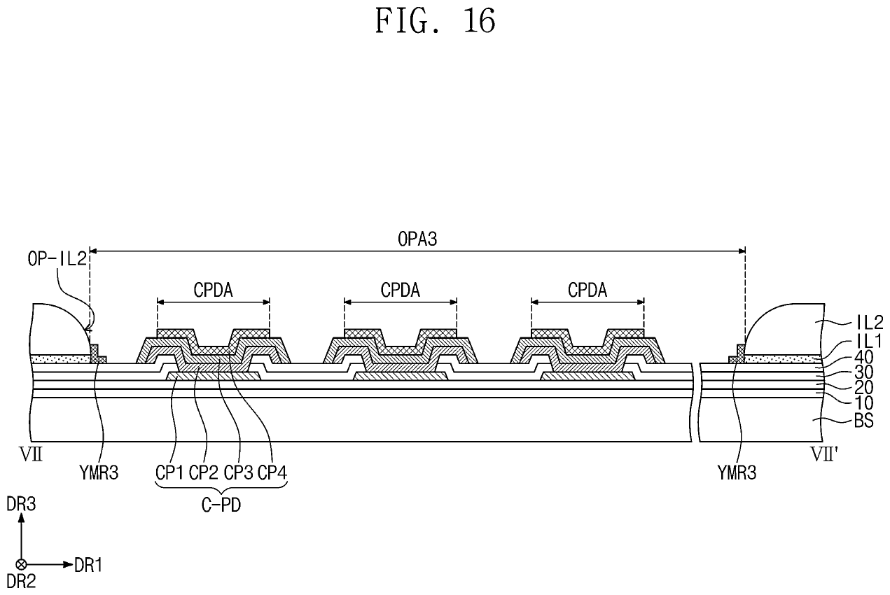

FIG. 16 is a cross-sectional view taken along line VII-VII′ of FIG. 15 according to an embodiment of the inventive concept.

Referring to FIG. 16, a plurality of test pads C-PD may be arranged along a first direction DR1. The plurality of test pads C-PD may be spaced apart from each other by a predetermined distance, thereby preventing a short circuit between the plurality of test pads C-PD. The test pads C-PD and a third residue conductive pattern YMR3 may be spaced apart from each other by a predetermined distance. Accordingly, it may be possible to prevent a short circuit between the third residue conductive pattern YMR3 and the test pads C-PD.

The plurality of test pads C-PD may each include a plurality of conductive patterns CP1, CP2, CP3, and CP4 stacked along the thickness direction of the display panel DP (see FIG. 4). First conductive patterns CP1 of the test pads C-PD may be formed through the same process as the process through which the gate electrode GE (see FIG. 7) of the transistor TR (see FIG. 7) is formed, and include the same material as that of the gate electrode GE. Second conductive patterns CP2 of the test pads C-PD may be formed through the same process as the process through which the first connection electrode CN1 (see FIG. 7) is formed, and include the same material as that of the first connection electrode CN1. Third conductive patterns CP3 of the test pads C-PD may be formed through the same process as the process through which the second connection electrode CN2 (see FIG. 7) is formed, and include the same material as that of the second connection electrode CN2. Fourth conductive patterns CP4 of the test pads C-PD may be formed through the same process as the process through which the second sensing conductive layer CL2 (see FIG. 7) is formed, and include the same material as that of the second sensing conductive layer CL2.

An insulation opening OP-IL2 (or third opening) overlapping a test pad region CPA (see FIG. 16) may be defined in a first sensing insulation layer IL2. The insulation opening OP-IL2 may entirely overlap a plurality of sub test pad regions CPDA. An inner side surface of the first sensing insulation layer IL2 defining the insulation opening OP-IL2 may be spaced apart from the sub test pad region CPDA by a predetermined distance. The first sensing insulation layer IL2 might not be in contact with the test pads C-PD. The first sensing insulation layer IL2 might not overlap the test pads C-PD.

The third residue conductive pattern YMR3, including the same material as that of the second sensing conductive layer CL2 (see FIG. 7), may be defined on a border of the insulation opening OP-IL2. The third residue conductive pattern YMR3 may include the same material as that of the fourth conductive patterns CP4.

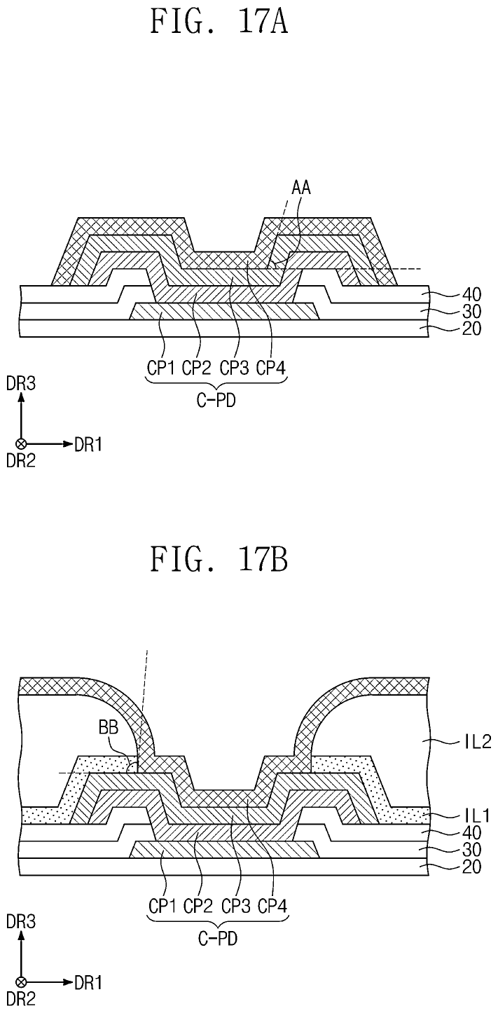

FIG. 17A is a cross-sectional view of a test pad according to an embodiment of the inventive concept. FIG. 17B is a cross-sectional view of a test pad according to Comparative Example.

Referring to FIG. 17A, a test pad C-PD, according to an embodiment of the inventive concept, might not overlap a base layer IL1 (see FIG. 17B) and a first sensing insulation layer IL2 (see FIG. 17B). Referring to FIG. 17B, a test pad C-PD, according to Comparative Example, may overlap the base layer IL1 and the first sensing insulation layer IL2. A fourth conductive pattern CP4 of the test pad C-PD according to FIG. 17B may be disposed on the first sensing insulation layer IL2 along an upper surface of the first sensing insulation layer IL2. The fourth conductive pattern CP4 disposed on the first sensing insulation layer IL2 may be bent at a second angle BB at a boundary of the first sensing insulation layer IL2. The second angle BB at which the fourth conductive pattern CP4 of the test pad C-PD in FIG. 17B is bent may be larger than a first angle AA at which the fourth conductive pattern CP4 of the test pad C-PD in FIG. 17A is bent. When the angle at which the fourth conductive pattern CP4 is bent becomes larger, pressure which is applied during pressing of the test pad C-PD and a test circuit board CFCB may be concentrated to cause damage to the fourth conductive pattern CP4. This may cause defects in the test pad C-PD.

Table 1 below shows the defect rate of Example in which the test pad C-PD does not overlap the first sensing insulation layer IL2, as illustrated in FIG. 17A, and the defect rate of Comparative Example in which the test pad C-PD overlaps the first sensing insulation layer IL2 as illustrated in FIG. 17B.

TABLE 1

| | Example | | | Comparative Example | | |
|---|---|---|---|---|---|---|
| Thickness of | 3.5 | 3.8 | 4 | 3.5 | 3.8 | 4 |
| first sensing | | | | | | |
| insulation | | | | | | |
| layer (μm) | | | | | | |
| Test (No.) | 60 | 119 | 60 | 60 | 120 | 60 |
| Defect (No.) | 0 | 0 | 0 | 4 | 9 | 2 |
| Defect Rate (%) | 0 | 0 | 0 | 6.7 | 7.5 | 3.3 |

Referring to FIGS. 17A, 17B, and Table 1, in Example, the defect rates are all 0% regardless of the thickness of the first sensing insulation layer IL2. However, in Comparative Example, when the thickness of the first sensing insulation layer IL2 is 3.5 μm, 3.8 μm, and 4 μm, the defect rate is 6.7%, 7.5%, and 3.3%, respectively. Therefore, in case of removing the first sensing insulation layer IL2 from the test pad C-PD, as in an embodiment of the inventive concept, it may be seen that the defect rate of the test pad C-PD is lowered.

In a display module according to an embodiment of the inventive concept, since an opening overlapping a pad region is defined in a sensing insulation layer including sensor an organic material, cracks on a conductive pattern or a short circuit between signal pads, caused by the sensing insulation layer, may be prevented.

In addition, since an insulation layer is disposed between a residue conductive pattern, formed on a border of the opening, and signal lines, a short circuit between the residue conductive pattern and the signal lines may be prevented.

Although the embodiments of the inventive concept have been described, it is understood that the inventive concept should not necessarily be limited to these embodiments but various changes and modifications can be made by one ordinary skilled in the art within the spirit and scope of the inventive concept. Therefore, the technical scope of the inventive concept should not necessarily be limited to the contents described in the detailed description of the specification.

What is claimed is:

1. A display module, comprising:
a display panel including a display region in which pixels are disposed, and a non-display region having a first pad region in which first signal pads are disposed, the first signal pads being electrically connected to the pixels through respective first signal lines; and
an input sensor disposed on the display panel, and including a sensing insulation layer including an organic material, and a sensing conductive layer,
wherein each of the first signal pads includes first conductive patterns stacked along a thickness direction of the display panel, and at least one of the first conductive patterns includes a same material as that of the sensing conductive layer,
wherein a first opening overlapping the first pad region is defined in the sensing insulation layer, and
wherein a first residue conductive pattern, including the same material as that of the sensing conductive layer, is disposed on a border of the first opening.

2. The display module of claim 1, wherein the first residue conductive pattern is spaced apart from the first signal pads by a predetermined distance.

3. The display module of claim 2, wherein a minimum distance between the first residue conductive pattern and the first signal pads is about 20 μm or more.

4. The display module of claim 1, wherein the sensing insulation layer does not overlap the first signal pads.

5. The display module of claim 1, wherein the first signal lines cross the first residue conductive pattern, and
wherein the display module further comprising an insulation layer disposed between the first signal lines and the first residue conductive pattern.

6. The display module of claim 5, wherein each of the pixels comprises a transistor and a light-emitting element connected to the transistor, and
wherein the insulation layer includes a same material as that of at least one of insulation layers disposed between the transistor and the light-emitting element.

7. The display module of claim 1, wherein each of the pixels comprises a transistor and a light-emitting element connected to the transistor,
wherein the transistor comprises a semiconductor pattern and a gate electrode disposed on the semiconductor pattern, and
wherein the display panel further comprises first and second connection electrodes which connect the transistor to the light-emitting element.

8. The display module of claim 7, wherein the first conductive patterns comprise:
a (1-1)-th conductive pattern including a same material as that of the gate electrode;
a (1-2)-th conductive pattern including a same material as that of the first connection electrode;
a (1-3)-th conductive pattern including a same material as that of the second connection electrode; and
a (1-4)-th conductive pattern including the same material as that of the sensing conductive layer, and
wherein the (1-1)-th conductive pattern to the (1-4)-th conductive pattern are electrically connected to each other.

9. The display module of claim 7, wherein each of the first signal lines comprises a same material as that of at least one of the gate electrode and the second connection electrode.

10. The display module of claim 7, wherein each of the first signal lines comprises a same material as that of the second connection electrode, and
wherein an insulation layer is disposed between the first signal lines and the first residue conductive pattern, and the first residue conductive pattern is spaced at least about 20 μm apart from an end of the insulation layer.

11. The display module of claim 1, wherein the non-display region further comprises a second pad region in which second signal pads are disposed, the second signal pads being spaced further apart from the display region than the first signal pads are and the second signal pads are electrically connected to the pixels respectively through second signal lines,
wherein each of the second signal pads comprises second conductive patterns stacked along a thickness direction of the display panel, and at least one of the second conductive patterns includes the same material as that of the sensing conductive layer,
wherein a second opening overlapping the second pad region is defined in the sensing insulation layer, and
wherein a second residue conductive pattern, including the same material as that of the sensing conductive layer, is disposed on a border of the second opening.

12. The display module of claim 11, wherein the second residue conductive pattern is spaced apart from the second signal pads by a predetermined distance.

13. The display module of claim 11, wherein the second signal lines comprise:
a (2-1)-th signal line; and
a (2-2)-th signal line which electrically connects between the (2-1)-th signal line and the second signal pads,
wherein the (2-2)-th signal line crosses the second residue conductive pattern, and
wherein the display module further comprising an insulation layer disposed between the (2-2)-th signal line and the second residue conductive pattern.

14. The display module of claim 13, wherein each of the pixels comprises a transistor and a light-emitting element connected to the transistor,
wherein the transistor comprises a semiconductor pattern and a gate electrode disposed on the semiconductor pattern,
wherein the display panel further comprises first and second connection electrodes which connect the transistor to the light-emitting element,
wherein the (2-1)-th signal line includes the same material as that of the sensing conductive layer, and
wherein the (2-2)-th signal line includes a same material as that of the second connection electrode.

15. The display module of claim 11, wherein a minimum distance between the second signal pads is about 10 μm or more.

16. The display module of claim 11, wherein the non-display region further comprises a third pad region in which test pads are disposed, the test pads being spaced further apart from the display region than the second signal pads are and the test pads being electrically connected to the pixels respectively through third signal lines,
wherein each of the test pads comprises third conductive patterns stacked along a thickness direction of the display panel, and at least one of the third conductive patterns includes the same material as that of the sensing conductive layer,
wherein a third opening overlapping the third pad region is defined in the sensing insulation layer, and
wherein a third residue conductive pattern, including the same material as that of the sensing conductive layer, is disposed on a border of the third opening.

17. The display module of claim 16, wherein the test pads are bonded to a test circuit board through a conductive adhesive layer.

18. An electronic apparatus, comprising:
a display panel including a display region in which pixels are disposed, and a non-display region having first and second pad regions in which first and second signal pads, electrically connected to the pixels respectively through signal lines, are disposed;
an input sensor disposed on the display panel, and including a sensing insulation layer including an organic material, and a sensing conductive layer;
a data driver disposed on the non-display region, and electrically connected to the first signal pads by a first conductive adhesive layer; and
a flexible circuit board disposed on the non-display region, and electrically connected to the second signal pads by a second conductive adhesive layer,
wherein each of the first signal pads includes first conductive patterns stacked along a thickness direction of the display panel, and at least one of the first conductive patterns includes a same material as that of the sensing conductive layer,
wherein a first opening overlapping the first pad region is defined in the sensing insulation layer, and
wherein a first residue conductive pattern, including the same material as that of the sensing conductive layer, is disposed on a border of the first opening.

19. The electronic apparatus of claim 18, wherein the first residue conductive pattern is spaced apart from the first signal pads by a predetermined distance.

20. The electronic apparatus of claim 18, wherein the non-display region further comprises a second pad region in which second signal pads are disposed, the second signal pads being spaced further apart from the display region than the first signal pads are and the second signal pads are electrically connected to the pixels respectively through second signal lines,
wherein each of the second signal pads comprises second conductive patterns stacked along a thickness direction of the display panel, and at least one of the second conductive patterns includes the same material as that of the sensing conductive layer,
wherein a second opening overlapping the second pad region is defined in the sensing insulation layer, and
wherein a second residue conductive pattern, including the same material as that of the sensing conductive layer, is disposed on a border of the second opening.
